(19) United States
(12) Patent Application Publication
(10) Pub. No.: US 2026/0353749 A1
(43) Pub. Date: Nov. 5, 2026

(54) SEMICONDUCTOR DEVICES WITH GATE-COVERED FIELD RELIEF LAYERS AND METHODS OF FABRICATION THEREOF

(71) Applicant: TEXAS INSTRUMENTS INCORPORATED, Dallas, TX (US)

(72) Inventors: Bikram Kishore Mahajan, Richardson, TX (US); Pinghai Hao, Plano, TX (US); Dhanoop Varghese, Plano, TX (US)

(21) Appl. No.: 19/194,769

(22) Filed: Apr. 30, 2025

(51) Int. Cl. H10D 64/00; H10D 30/01; H10D 30/65; H10D 64/01

(52) U.S. Cl. CPC H10D 64/118; H10D 30/0281; H10D 30/65; H10D 64/01

(57) ABSTRACT

Semiconductor devices and fabrication methods thereof are described. For example, a method of fabricating a semiconductor device includes forming a first field relief layer partially in a semiconductor layer, the first field relief layer being formed via a local oxidation of silicon (LOCOS) process. The method further includes forming a second field relief layer at least partially on the first field relief layer, the second field relief layer including nitride. The method further includes forming a gate electrode, the gate electrode disposed partially on the first field relief layer and covering the second field relief layer. The method further includes forming a drain region and a source region, the drain region being proximate to a first end of the first field relief layer and the source region being proximate to a second end of the first field relief layer.

### TECHNICAL FIELD

The present disclosure relates to the field of semiconductor devices, and more particularly, but not exclusively, to drain extended metal oxide semiconductor (DeMOS) transistors and other drain extended transistors.

### BACKGROUND

DeMOS transistors are field effect transistors (FETs) that are utilized in high power applications. A DeMOS transistor is an example of a laterally diffused metal oxide semiconductor (LDMOS) transistor or, more generally, a drain extended transistor. In drain extended transistors, the drain and source have a relatively large spacing between them, as compared with MOS transistors for other applications (e.g., logic applications), and lateral diffusions are used to produce a well-controlled channel region under the gate. The operational performance of drain extended transistors is generally affected by parameters including, for example, a specific on-resistance (Rsp) and a breakdown voltage (BV). A desirable approach for drain extended transistors is to decrease Rsp and increase BV, or at least to improve one parameter without adversely affecting the other parameter in a significant manner.

### SUMMARY

The present disclosure describes semiconductor devices with field relief layers and methods of fabrication thereof. This summary is not an extensive overview of the disclosure. Rather, a purpose of the summary is to present some examples of the present disclosure in a simplified form as a prelude to a more detailed description that is presented later.

In one example, a semiconductor device includes a semiconductor layer, a drain region, and a source region, the drain region and the source region being disposed in the semiconductor layer. The semiconductor device further includes a first field relief layer disposed partially in the semiconductor layer between the drain region and the source region. The semiconductor device further includes a gate electrode disposed between the drain region and the source region, the gate electrode disposed partially on the first field relief layer. The semiconductor device further includes a second field relief layer disposed at least partially on the first field relief layer and covered by the gate electrode.

In another example, a semiconductor device includes a semiconductor layer, a drain region, and a source region, the drain region and the source region being disposed in the semiconductor layer. The semiconductor device further includes a silicon oxide layer disposed partially in the semiconductor layer between the drain region and the source region. The semiconductor device further includes a gate stack disposed between the drain region and the source region, the gate stack including a gate electrode and a gate oxide layer, the gate electrode disposed partially on the silicon oxide layer and partially on the gate oxide layer. The semiconductor device further includes a nitride layer disposed partially on the silicon oxide layer, partially on the gate oxide layer, and covered by the gate electrode.

In an additional example, a method of fabricating a semiconductor device includes forming a first field relief layer partially in a semiconductor layer, the first field relief layer being formed via a local oxidation of silicon (LOCOS) process. The method further includes forming a second field relief layer at least partially on the first field relief layer, the second field relief layer including nitride. The method further includes forming a gate electrode, the gate electrode disposed partially on the first field relief layer and covering the second field relief layer. The method further includes forming a drain region and a source region, the drain region being proximate to a first end of the first field relief layer and the source region being proximate to a second end of the first field relief layer.

### BRIEF DESCRIPTION OF THE DRAWINGS

FIG. 1 is a cross-sectional view of a semiconductor device with field relief layers in accordance with an example of the present disclosure;

FIGS. 2A-2K are cross-sectional views of a process flow for forming a semiconductor device with field relief layers in accordance with the example of FIG. 1;

FIG. 3 is a cross-sectional view of a semiconductor device with field relief layers in accordance with another example of the present disclosure; and

FIGS. 4A-4L are cross-sectional views of a process flow for forming a semiconductor device with field relief layers in accordance with the example of FIG. 3.

FIG. 5 is a cross-sectional view of a semiconductor device with field relief layers in accordance with yet another example of the present disclosure; and

FIGS. 6A-6N are cross-sectional views of a process flow for forming a semiconductor device with field relief layers in accordance with the example of FIG. 5.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately,” preceding a value mean +/−10-20 percent (%) of the stated value. The terms “substantially” or “substantially equal” means values within ±2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

A DeMOS transistor as used herein is an example of an LDMOS transistor or, more generally, a drain extended transistor. As such, technical advantages and examples of DeMOS transistors described in the present disclosure are also applicable to fabrication and operation of other LDMOS transistors, as well as other drain extended transistors. Accordingly, while some examples of the present disclosure are described herein in the context of DeMOS transistors-particularly, n-type channel DeMOS (DeNMOS) transistors, other examples of the present disclosure can be implemented in p-type channel DeMOS (DePMOS) transistors, groups of DeNMOS and DePMOS transistors, referred to as complimentary drain extended MOS (DeCMOS) transistors, as well as in LDMOS and other drain extended transistors.

As mentioned, the operational performance of an DeMOS transistor is generally affected by a tradeoff between a specific on-resistance (Rsp) parameter and a breakdown voltage (BV) parameter. For example, approaches that seek to achieve the advantage of a higher BV by increasing the body area of the device consequently lead to the disadvantage of a higher Rsp. Similarly, approaches that seek to decrease Rsp generally come at the cost of decreasing the BV rating. Accordingly, desirable approaches for DeMOS transistors and other drain extended transistors that effectively manage this tradeoff provide technical advantages.

However, certain device reliability issues can affect device parameters (e.g., BV, Rsp, etc.). For example, device reliability issues such as time-dependent dielectric breakdown (TDDB), channel hot carrier (CHC) degradation, and gate oxide integrity (GOI) degradation can adversely affect DeMOS transistors and other drain extended transistors.

TDDB is a condition where a dielectric material of a device degrades over time, e.g., due to the presence of a relatively high electric field, such that the electrical-insulating properties of the dielectric break down allowing a conductive path to form through the material. For example, in the case of a dielectric layer such as a gate oxide layer, TDDB can adversely affect the gate oxide layer disposed below a gate electrode by causing the accumulation of charges in the gate oxide layer. Such charge accumulation leads to gate oxide leakage current-which results in lowering of the BV of the device, as well as shifting other device parameters. This condition may also be referred to, in the case of gate dielectrics, as GOI degradation.

CHC degradation, on the other hand, is a condition where high-energy (“hot”) charge carriers are injected into the gate oxide or other dielectric material due to the presence of relatively strong electric fields. However, similar to TDDB, CHC degradation causes undesirable shifts in BV, Rsp, a drain-source on-resistance (Rdson) and other device parameters.

When a DeMOS transistor or other drain extended transistor utilizes a field relief layer such as a silicon oxide layer formed via a local oxidation of silicon (LOCOS) process, TDDB, CHC and/or GOI degradation tend to be more significant in and around the area of the bird's beak profile formed at the end portion of the silicon oxide layer under the gate electrode (e.g., proximate the source). One reason for this condition is due to the thickness transition of the dielectric material at the bird's beak profile under the gate electrode. For example, electric field lines at the transition of the dielectric material (or thickness) can be distorted (e.g., field strength and/or density changes) such that performance and/or stability of the DeMOS transistor may be adversely impacted as a result.

To address the above and other technical challenges in DeMOS and other drain extended transistors, examples of the present disclosure describe semiconductor devices with field relief layers formed/disposed to mitigate TDDB, CHC and/or GOI degradation, as well as other reliability, performance and/or stability issues, without compromising device parameters (e.g., BV, Rsp, etc.). While examples of the disclosure may be expected to provide improvements such as may be described herein, no particular result is a requirement of the present invention unless explicitly recited in a particular claim.

In one example, a semiconductor device includes a semiconductor layer, a drain region, and a source region, the drain region and the source region being disposed in the semiconductor layer. The semiconductor device further includes a first field relief layer disposed partially in the semiconductor layer between the drain region and the source region. The semiconductor device further includes a gate electrode disposed between the drain region and the source region, the gate electrode disposed partially on the first field relief layer. The semiconductor device further includes a second field relief layer disposed at least partially on the first field relief layer and covered by the gate electrode.

In some examples, the second field relief layer includes nitride. Further, the second field relief layer can be disposed on a first end portion of the first field relief layer, the first end portion being proximate the source region. The first end portion can include a bird's beak profile, in some examples.

Still further, in some examples, the second field relief layer is disposed above a drift region in the semiconductor layer, the drift region extending from the drain region towards the source region.

In other examples, the semiconductor device further includes a gate dielectric layer disposed on the semiconductor layer, and wherein the gate electrode is partially disposed on the gate dielectric layer. Further, the second field relief layer can be partially disposed on the gate dielectric layer.

In some other examples, the gate dielectric layer has a first thickness below the second field relief layer and a second thickness below the gate electrode, the first thickness being different than the second thickness.

In another example, a semiconductor device includes a semiconductor layer, a drain region, and a source region, the drain region and the source region being disposed in the semiconductor layer. The semiconductor device further includes a silicon oxide layer disposed partially in the semiconductor layer between the drain region and the source region. The semiconductor device further includes a gate stack disposed between the drain region and the source region, the gate stack including a gate electrode and a gate oxide layer, the gate electrode disposed partially on the silicon oxide layer and partially on the gate oxide layer. The semiconductor device further includes a nitride layer disposed partially on the silicon oxide layer, partially on the gate oxide layer, and covered by the gate electrode.

The nitride layer, in some examples, is disposed on a portion of the silicon oxide layer proximate the source region, the portion of the silicon oxide layer including a bird's beak profile. Moreover, the nitride layer can be disposed above a drift region in the semiconductor layer, the drain region extending from the drain region towards the source region. Still further, the gate oxide layer can have a first thickness below the nitride layer and a second thickness below the gate electrode, the first thickness being less than the second thickness.

In an additional example, For example, a method of fabricating a semiconductor device includes forming a first field relief layer partially in a semiconductor layer, the first field relief layer being formed via a local oxidation of silicon (LOCOS) process. The method further includes forming a second field relief layer at least partially on the first field relief layer, the second field relief layer including nitride. The method further includes forming a gate electrode, the gate electrode disposed partially on the first field relief layer and covering the second field relief layer. The method further includes forming a drain region and a source region, the drain region being proximate to a first end of the first field relief layer and the source region being proximate to a second end of the first field relief layer.

The method also includes, in some examples, forming a gate dielectric layer on the semiconductor layer, the gate dielectric layer being partially below the gate electrode and partially below the second field relief layer. The gate dielectric layer can include a first layer formed via a first process using a first temperature and a second layer formed on the first layer via a second process using a second temperature, the first temperature being greater than the second temperature.

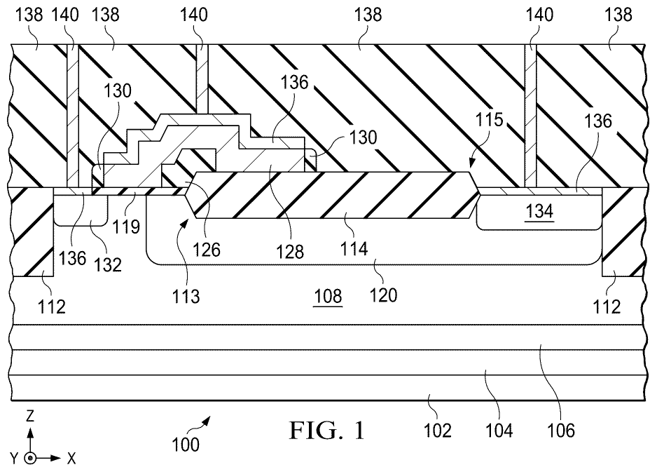

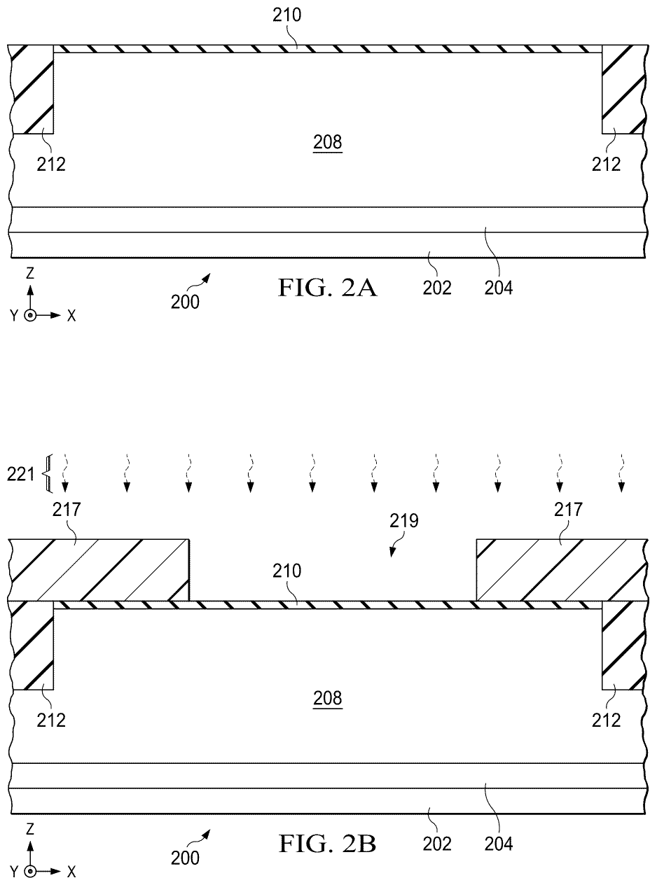

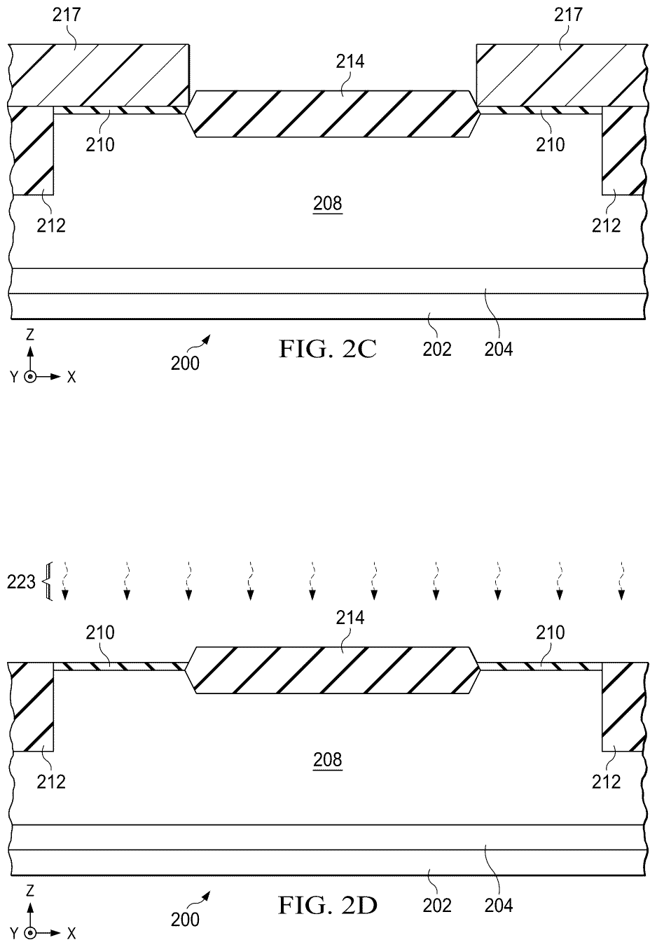

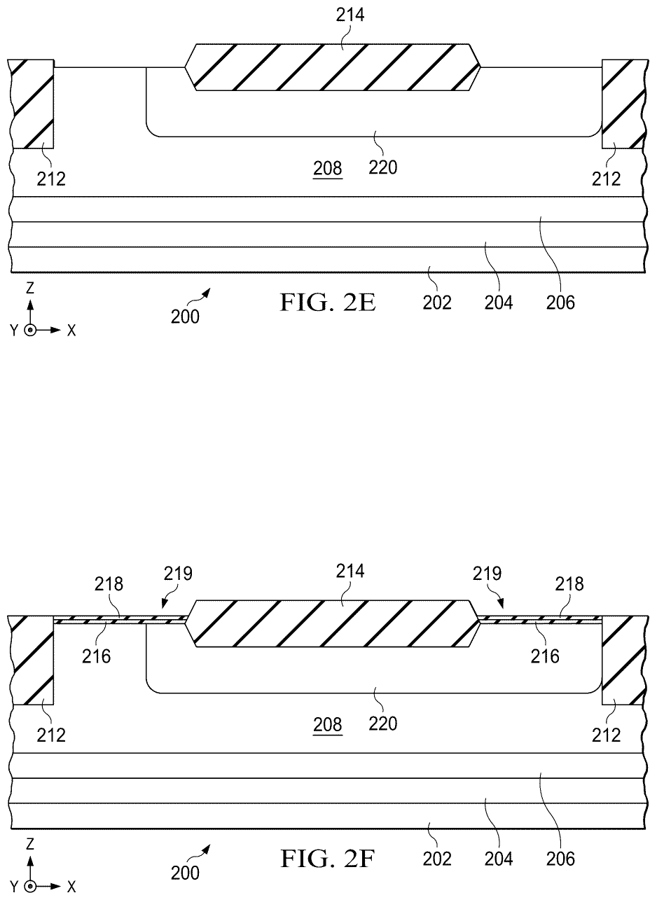

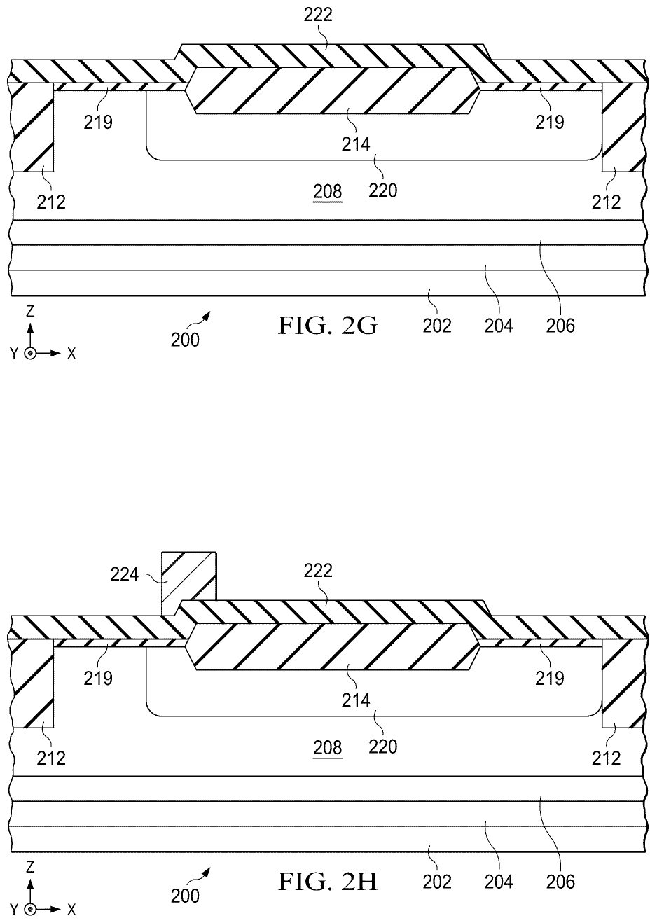

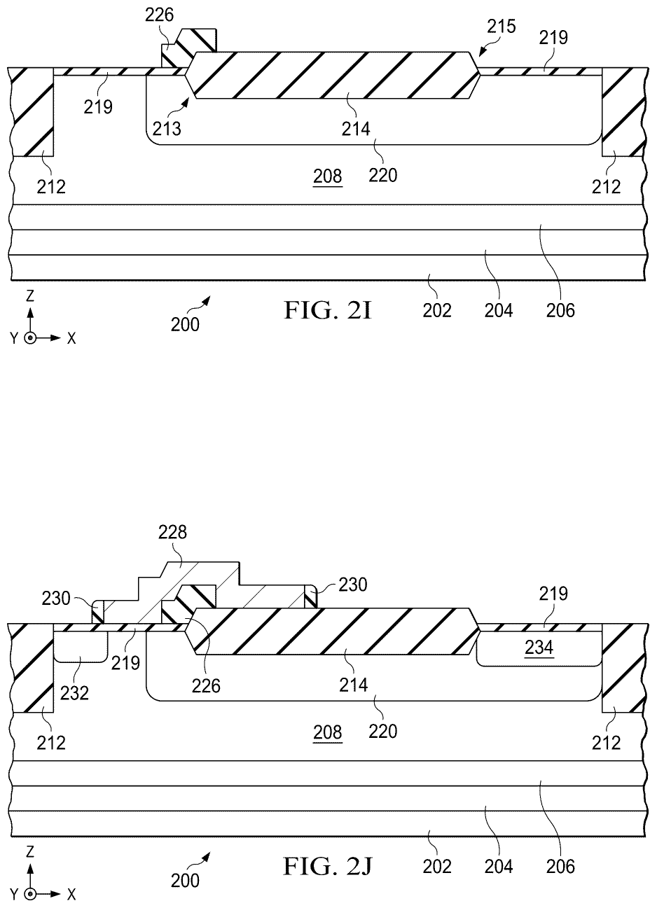

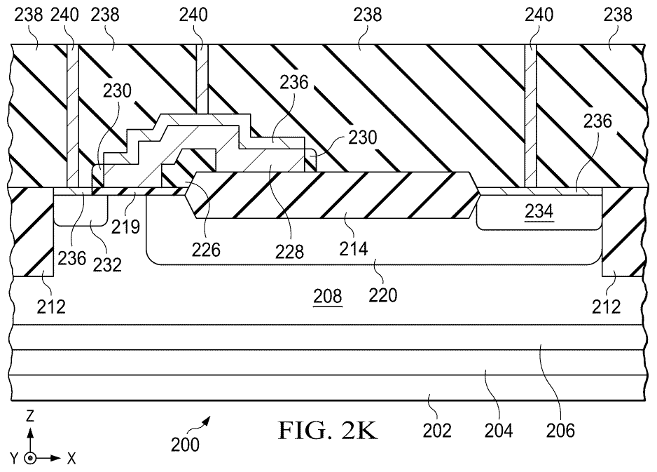

In some examples, e.g., as will be described herein in the context of FIGS. 1 and 2A through 2K, the second field relief layer is formed after the forming of the first layer and the forming of the second layer of the gate dielectric layer.

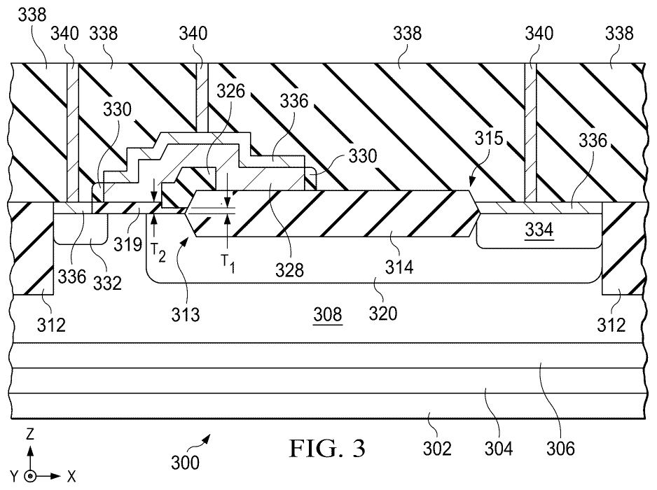

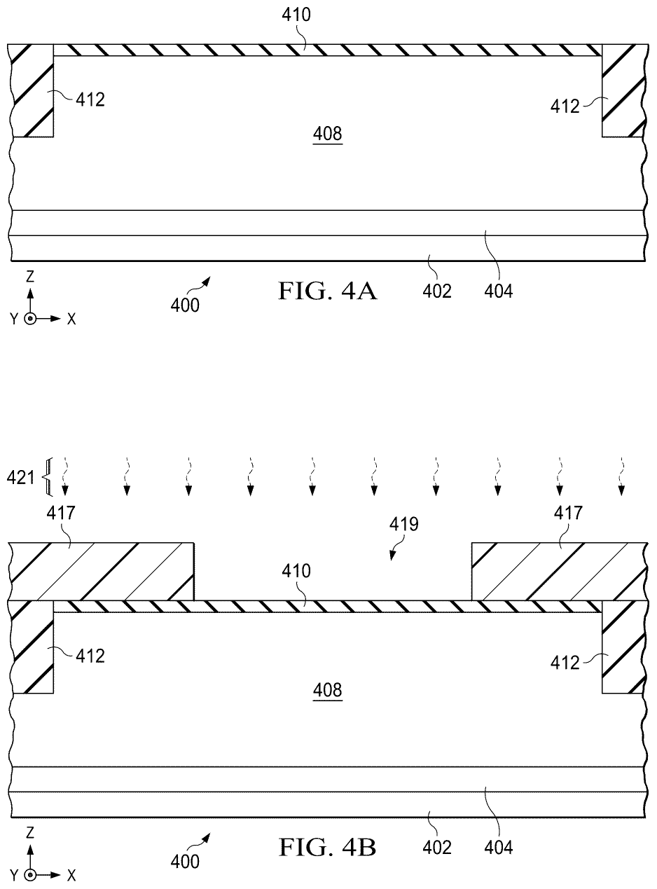

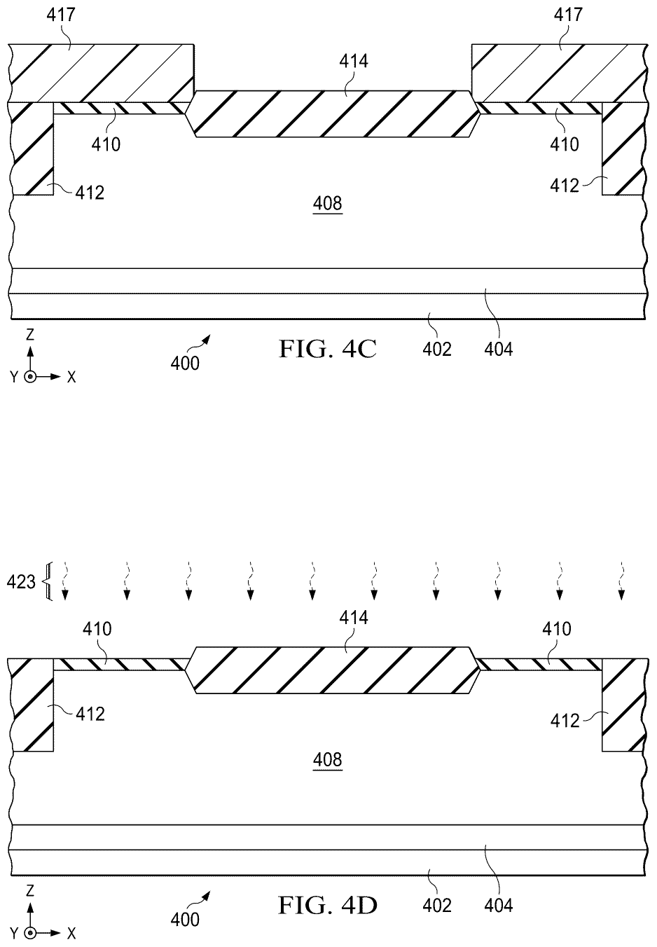

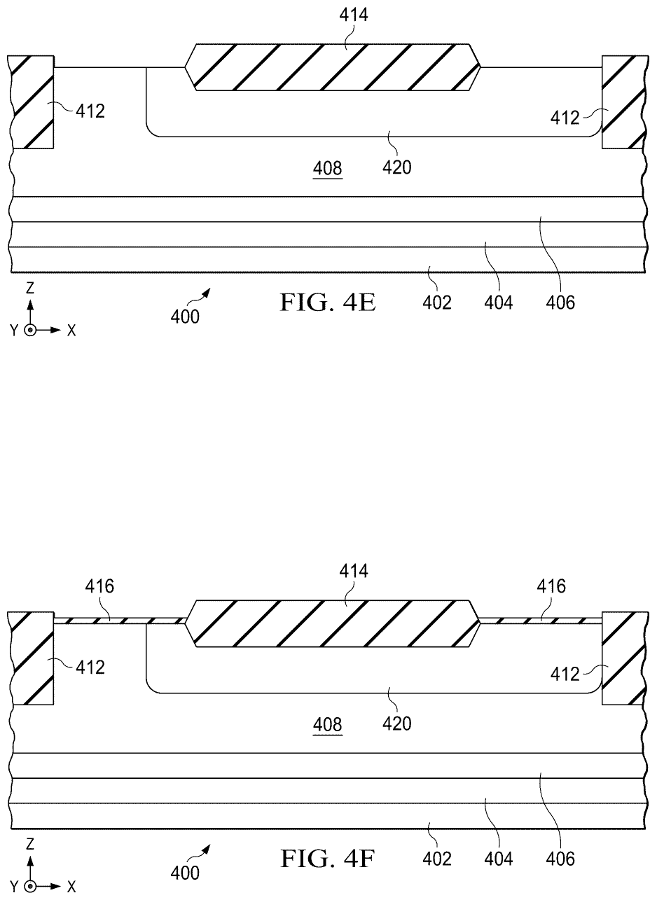

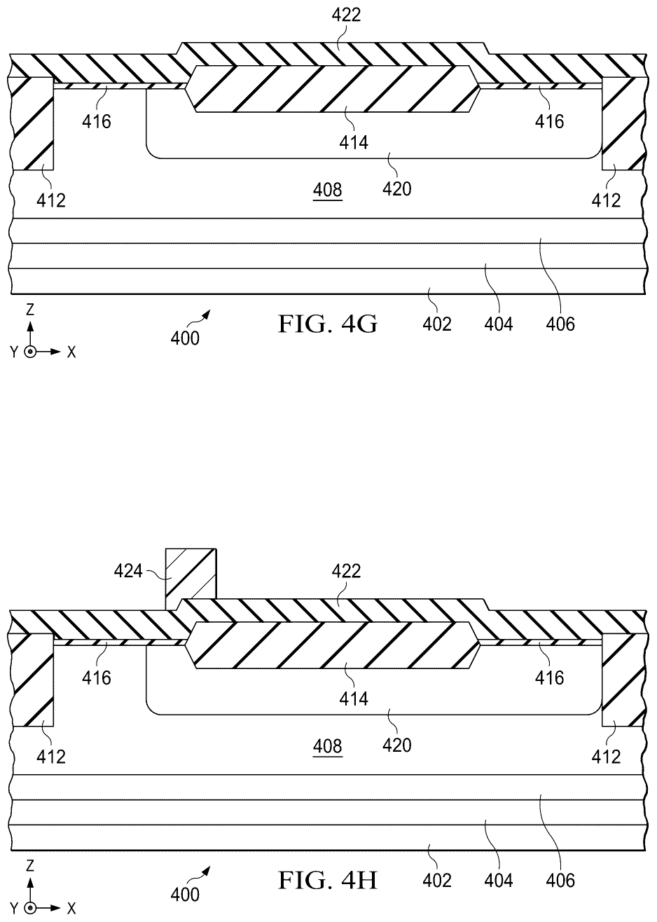

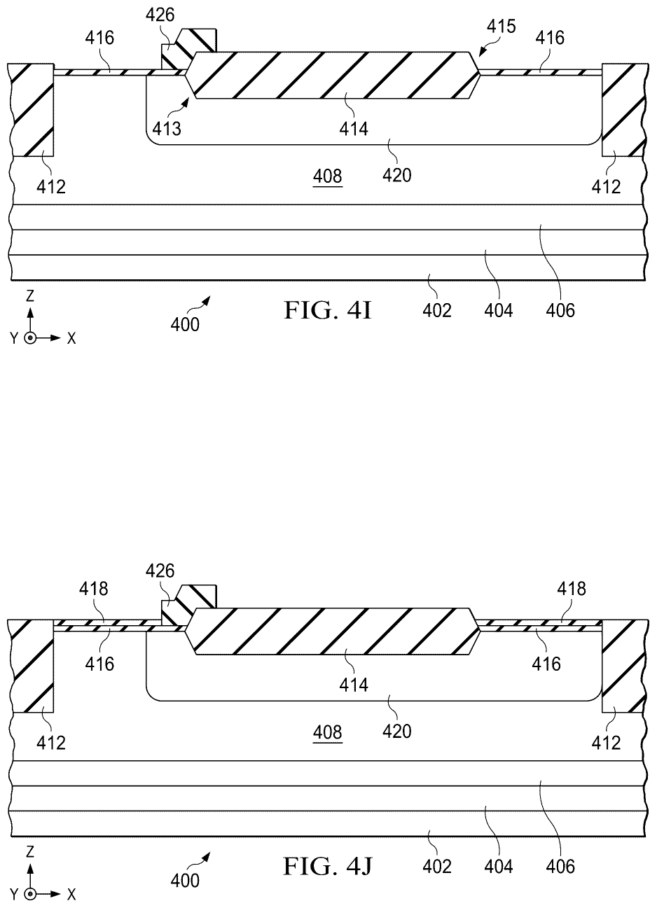

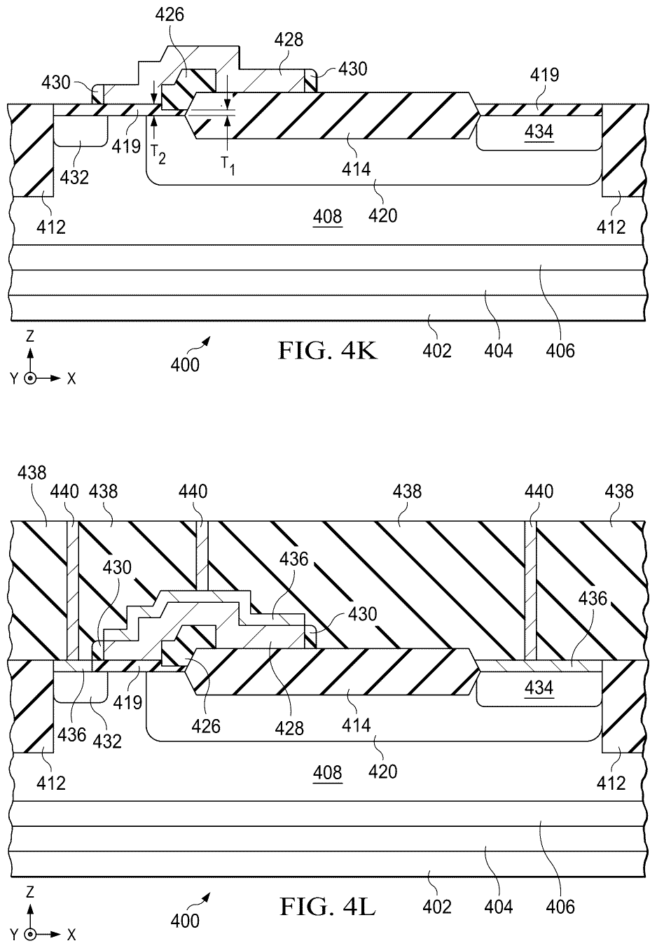

In some other examples, e.g., as will be described herein in the context of FIGS. 3 and 4A through 4M, the second field relief layer is formed between the forming of the first layer and the forming of the second layer of the gate dielectric layer.

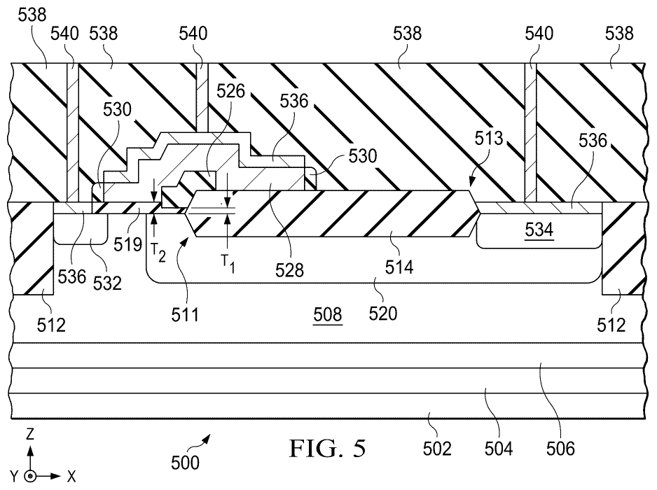

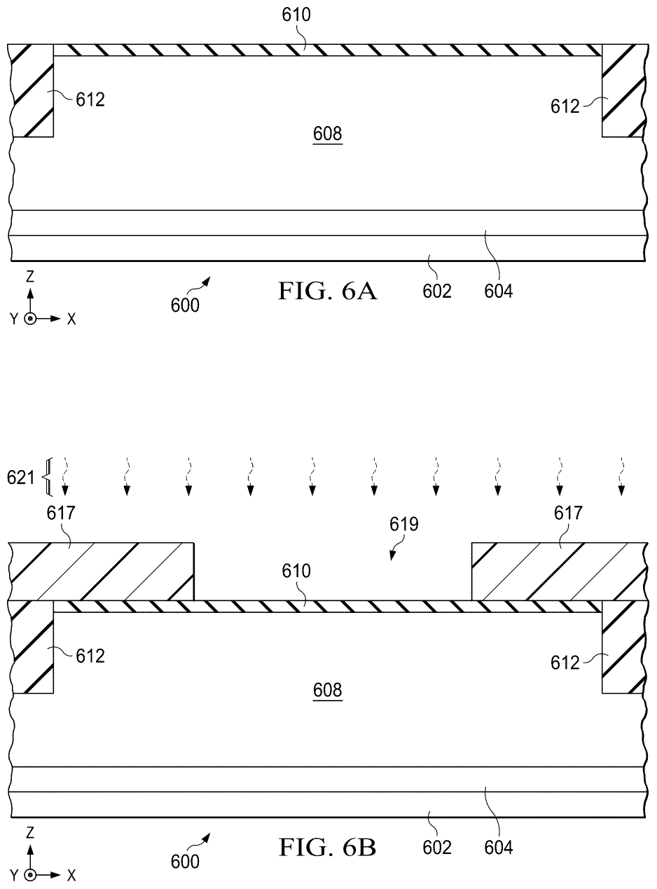

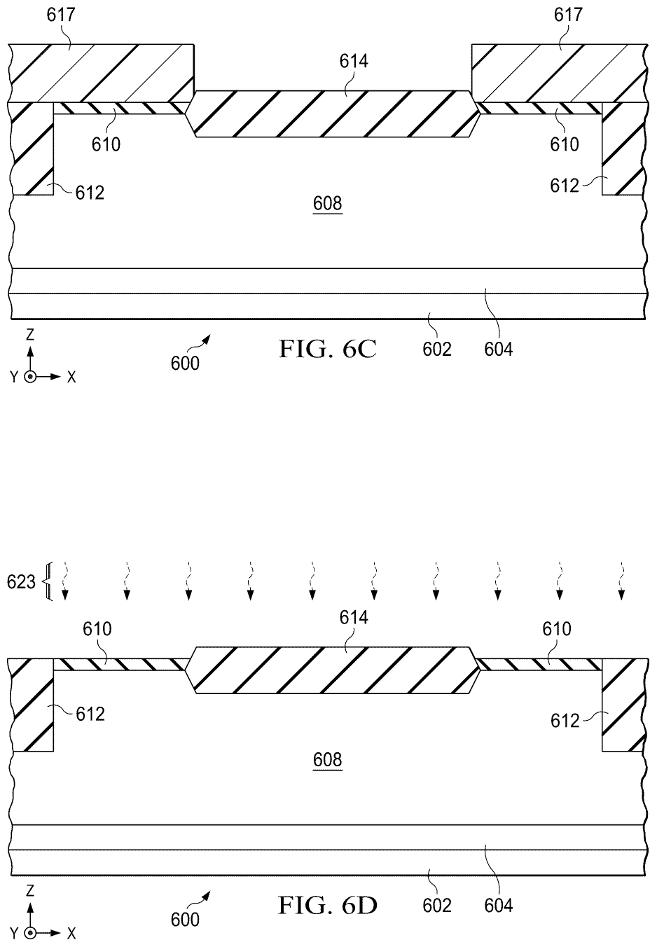

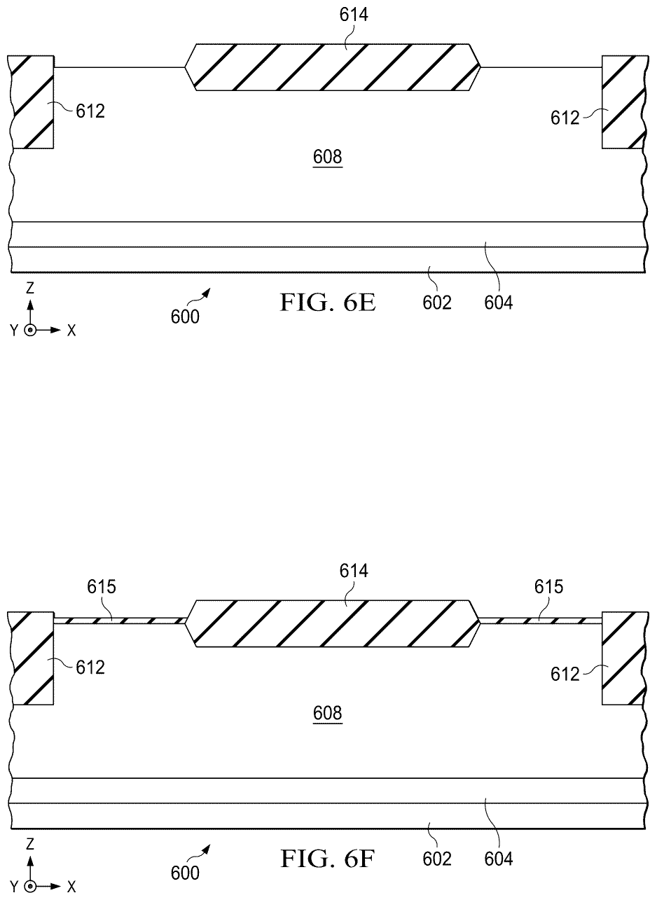

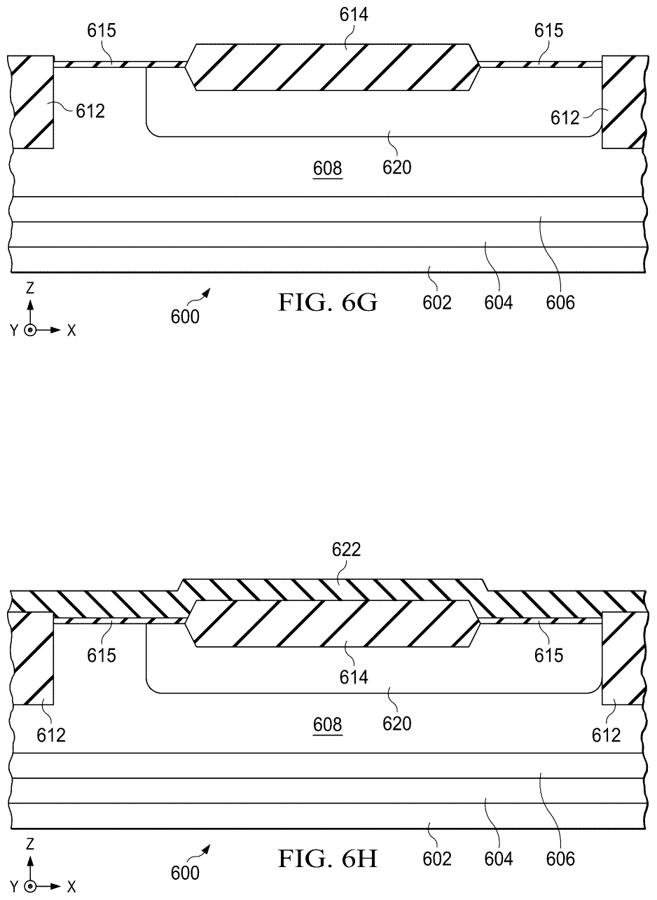

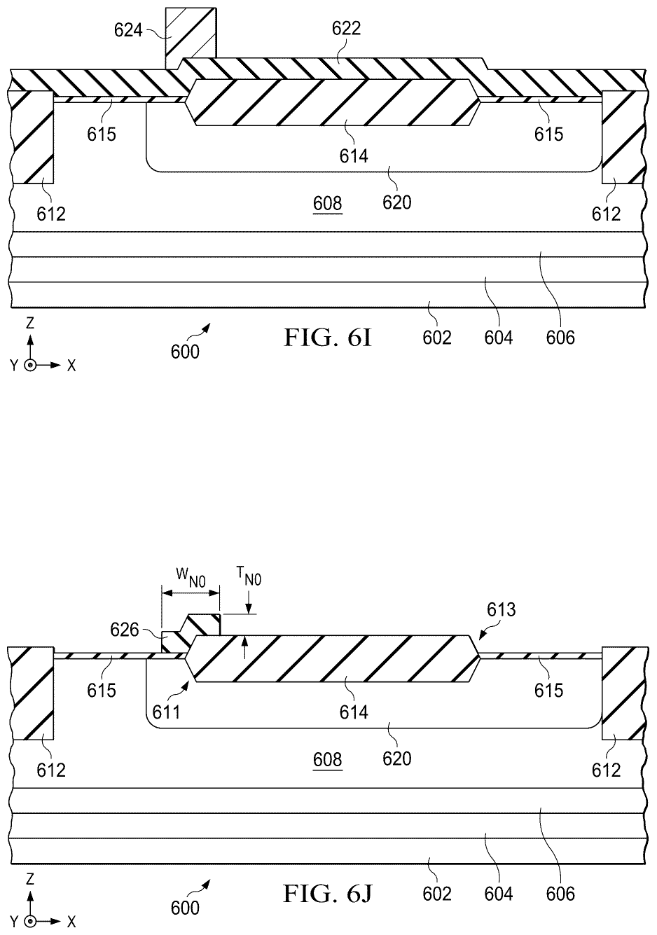

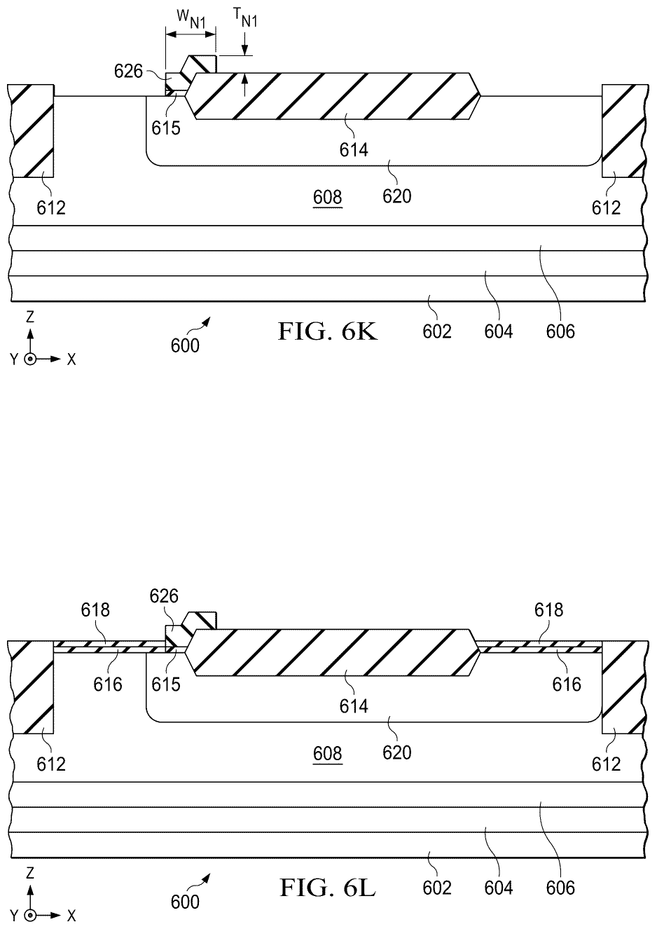

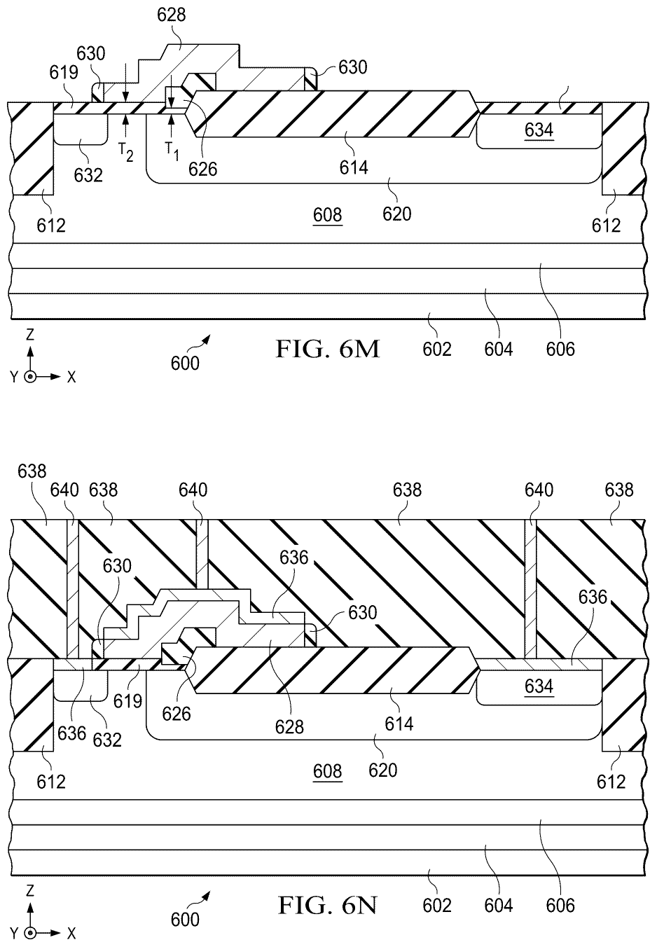

Still further, in other examples, e.g., as will be described herein in the context of FIGS. 5 and 6A through 6N, the second field relief layer is formed before the forming of the first layer and the forming of the second layer of the gate dielectric layer. In addition, the method can include removing a first portion of the second field relief layer before the forming of the first layer and the forming of the second layer of the gate dielectric layer, wherein a second portion of the second field relief layer, remaining after the removing of the first portion, is proximate the source region.

In some further examples, the gate dielectric layer has a first thickness below the second field relief layer and a second thickness below the gate electrode, the first thickness being different than the second thickness.

In other examples, the method includes reducing a lateral dimension of the second field relief layer (e.g., a blanket nitride pullback) before forming the gate electrode.

Advantageously, in the case of a DeMOS transistor (or, more generally, a drain extended transistor) with a LOCOS-formed field relief layer, placement of a nitride-based field relief layer (e.g., field plate) on the source-side bird's beak of the LOCOS-formed field relief layer mitigates TDDB, CHC degradation, and GOI degradation-while maintaining acceptable BV and Rsp parameters.

Referring now to FIG. 1, a semiconductor device 100 is shown. The semiconductor device 100 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 100 is shown as including a DeMOS transistor, additional transistors (e.g., DeMOS and/or other transistor types) and/or other components that are not expressly shown may be integrated as part of semiconductor device 100 in various other examples. Also, while the DeMOS transistor in FIG. 1 is illustrated as a DeNMOS transistor, in one or more alternative examples, a DePMOS transistor can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 100 includes a semiconductor substrate 102, a first buried layer 104 disposed on the semiconductor substrate 102, a second buried layer 106 disposed on the first buried layer 104, and a semiconductor layer 108 disposed on the second buried layer 106. In some examples, the semiconductor layer 108 can be formed by an epitaxial process, and thus can be referred to as an epitaxial or “epi” layer 108. In the FIG. 1 example, the semiconductor substrate 102 is a p-type substrate, the second buried layer 106 is p-type buried layer (PBL 106), and the semiconductor layer 108 is a p-type semiconductor layer, while the first buried layer 104 is an n-type buried layer (NBL 104). In some examples, the PBL 106 has a dopant concentration greater than the semiconductor layer 108 and can be used to implement reduced surface field (RESURF) principles for safe operating area (SOA) improvement for the semiconductor device 100. While two buried layers, e.g., the NBL 104 and the PBL 106, are shown in FIG. 1, other examples may include one or the other of the buried layers, or no buried layers.

Isolation regions 112 are disposed in the semiconductor layer 108. FIG. 1, being a cross-sectional view, illustrates the semiconductor device 100 (also referred to herein as the DeNMOS transistor 100) disposed between a pair of the isolation regions 112. The isolation regions 112 may laterally surround the DeNMOS transistor 100 in a top-down view (e.g., a layout view). In some examples, the isolation regions 112 are shallow trench isolation (STI) regions, while in other examples, the isolation regions 112 are deep trench (DT) regions, both STI and DT regions, or some combination thereof. Various other forms of component (e.g., transistor) isolation can be additionally or alternatively implemented in other examples.

As further shown, the DeNMOS transistor 100 includes a first field relief layer 114 disposed partially in the semiconductor layer 108 and partially above the semiconductor layer 108. The first field relief layer 114 is formed via a local oxidation of silicon (LOCOS) process, thus also being referred to herein as a LOCOS layer 114. The LOCOS layer 114, as will be further described below in the context of the FIGS. 2A-2K examples, is composed of a silicon oxide material and includes a first end portion 113 and a second end portion 115. First and second end portions 113 and 115 each have a bird's beak profile as is a common result of the LOCOS process.

The DeNMOS transistor 100 also includes a gate dielectric (e.g., gate oxide) layer 119 disposed on the semiconductor layer 108 adjacent the first end portion 113 of the LOCOS layer 114. The gate dielectric layer 119 is part of a gate stack as will be further described below.

A second field relief layer 126 is disposed partially on the gate dielectric layer 119 and partially on the LOCOS layer 114, more particularly, on the first end portion 113 (the bird's beak) of the LOCOS layer 114. The second field relief layer 126, as will be further described below in the context of the FIGS. 2A-2K examples, is composed of a nitride material. As shown, the second field relief layer 126 extends along the gate dielectric layer 119 and slopes upward in the Z direction along the first end portion 113 of the LOCOS layer 114 before terminating at an edge along a top non-sloped surface of the LOCOS layer 114. Advantageously, the second field relief layer 126 (also referred to as a nitride layer 126 or a nitride field plate 126) reduces a vertical electric field strength in the area under the second field relief layer 126 thus mitigating the above-described adverse effects of TDDB, CHC degradation, GOI degradation, and/or other device performance, reliability and/or stability issues.

The DeNMOS transistor 100 also includes an n-type drain drift region 120 disposed in the semiconductor layer 108, an n-type source region 132, and an n-type drain region 134 disposed in the drain drift region 120. The LOCOS 114 is disposed between the source region 132 and the drain region 134, partially above a surface of the semiconductor layer 108 and partially below the surface and in the drain drift region 120.

In some examples, DeNMOS transistor 100 can include a body contact region (not expressly shown) in the semiconductor layer 108 with a p-type dopant(s). More particularly, a well implantation process can be performed to implant the body contact region between the source region 132 and the adjacent isolation region 112.

The DeNMOS transistor 100 further includes a gate stack. The gate stack includes the gate dielectric layer 119 disposed on a portion of the surface of the semiconductor layer 108. The gate stack further includes a gate electrode 128 disposed over the gate dielectric layer 119 and at least a portion of the LOCOS layer 114. As shown in FIG. 1, the gate electrode 128 extends along the gate dielectric layer 119 and slopes upward in the Z direction along the first end portion 113 of the LOCOS layer 114 proximate to the source region 132 before terminating at an edge along a top non-sloped surface of the LOCOS layer 114 (e.g., prior to reaching the second end portion 115 of the LOCOS layer 114 proximate to the drain region 134). In some examples, the edge of the gate electrode 128 above the top non-sloped surface of the LOCOS layer 114 may terminate closer to the source region 132 or closer to the drain region 134 as compared to where it is shown terminating in FIG. 1.

Further as shown, the gate electrode 128 covers the second field relief layer 126 (e.g., forming a gate-covered field relief layer 126) such that the second field relief layer 126 is encapsulated between the gate dielectric layer 119, the LOCOS layer 114, and the gate electrode 128.

In some examples, the gate electrode 128 includes a polysilicon material. In other examples, the gate electrode 128 includes a metal or other suitable material. A channel region may be considered to extend across a portion of the semiconductor layer 108 under the gate electrode 128 between the source region 132 and the drain region 134.

As further shown in FIG. 1, the DeNMOS transistor 100 includes sidewall spacer structures 130 along the lateral sides of the gate electrode 128. The sidewall spacer structures 130 in one example include an oxide layer and a nitride layer (not expressly shown). In another example, a nitride-only (or oxide-only) sidewall spacer structure can be implemented.

The DeNMOS transistor 100 also includes metal silicide layers 136 that respectively extend over the source region 132, the drain region 134, and the gate electrode 128. The DeNMOS transistor 100 can include a single or multilevel metallization structure, with a pre-metal dielectric (PMD) layer 138 and conductive metal (e.g., tungsten) contacts 140, terminating on the respective metal silicide layers 136 for the source region 132, the drain region 134, and the gate electrode 128. In some examples, the metal silicide layers 136 can be formed from a Cobalt silicide (CoSiₓ) material.

Referring now to FIGS. 2A-2K, cross-sectional views are shown of a process flow for forming a semiconductor device 200, e.g., a DeNMOS transistor, in accordance with an example of the present disclosure. More particularly, the process flow of FIGS. 2A-2K for the semiconductor device 200 may represent an example of the formation of the semiconductor device 100 (DeNMOS transistor 100) of FIG. 1. Accordingly, unless otherwise specified, reference numerals in the 200s in FIGS. 2A-2K correspond to the same layers and structures with reference numerals in the 100s in FIG. 1 (e.g., a semiconductor substrate 202 in FIGS. 2A-2K corresponds to semiconductor substrate 102 in FIG. 1, NBL 204 corresponds to NBL 104, and so on).

FIG. 2A depicts an intermediate stage of formation of the semiconductor device 200. As shown, the semiconductor device 200 includes a p-type semiconductor substrate 202 which may be implemented as a silicon wafer, a silicon-on-sapphire wafer, a silicon carbide wafer, or the like. In some examples, a p-type semiconductor layer 208 is epitaxially grown on the semiconductor substrate 202. Then, n-type dopants or impurities (e.g., phosphorus, arsenic, antimony, etc.) are implanted in the semiconductor layer 208 to form an n-type buried layer (NBL) 204. In other examples, n-type dopants or impurities (e.g., phosphorus, etc.) are introduced to the p-type semiconductor substrate 202, and then a p-type semiconductor layer 208 is epitaxially grown on the semiconductor substrate 202. In other examples, the NBL 204 can be omitted.

FIG. 2A further depicts initial portions of a LOCOS process for forming a field relief layer. For example, as shown, a pad oxide layer 210 (e.g., silicon dioxide) is formed on the semiconductor layer 208, e.g., using a thermal oxidation process or a deposition process such as chemical vapor deposition (CVD). In some examples, the pad oxide layer 210 can be about 20 nanometers (nm) in thickness in the Z direction and be referred to as a thin oxide layer.

As further shown in the FIG. 2A example, a plurality of isolation regions 212 are also formed in the semiconductor layer 208 for electrical isolation between the DeNMOS transistor, to be formed as part of semiconductor device 200, and any adjacent devices and/or components (not expressly shown). Although FIG. 2A, being a cross-sectional view, illustrates multiple isolation regions 212, the isolation regions 212 may laterally surround the DeNMOS transistor in a top-down view (e.g., a layout view).

Next, FIG. 2B depicts a result of a next intermediate formation stage wherein a silicon nitride layer 217 (e.g., about 90 nm in thickness in the Z direction) is first deposited across the pad oxide layer 210, then etched (e.g., a dry etch) using a mask layer (not expressly shown) to form a field relief opening 219. A portion of the silicon nitride layer 217 resides on each side of the field relief opening 219 and extends over a top surface of an adjacent isolation region 212 and adjacent portions of the corresponding pad oxide layer 210. The pad oxide layer 210 in the field relief opening 219 may be removed during the nitride etch exposing a portion of the silicon of the semiconductor layer 208 below the pad oxide layer 210. In some examples, at least a portion of the pad oxide layer 210 may remain in the field relief opening 219 to protect the surface of the silicon during subsequent process steps. While dependent on the type of DeNMOS transistor being formed, in some examples, the field relief opening 219 can have a width in the X direction of about 100-300 nm (e.g., about 200 nm).

As further shown in FIG. 2B, a thermal oxidation process 221 (e.g., a LOCOS process) is applied. The thermal oxidation process is a relatively high-temperature (e.g., about 700 to about 1200 degrees Celsius (°C)) furnace oxidation that causes the silicon area of the semiconductor layer 208, uncovered by the silicon nitride layer 217 in the field relief opening 219, to oxidize and form a relatively thick layer of silicon dioxide in the field relief opening 219, e.g., a LOCOS layer 214, as shown in FIG. 2C.

The LOCOS layer 214 in FIG. 2C is formed partially above and partially below a top surface of the semiconductor layer 208. As an example, a LOCOS thickness (in the Z direction) can be about 100 nm, although the thickness can be dependent on the width of the field relief opening 219 and the operating parameters of the furnace oxidation. As is typical of a LOCOS process, the portions of the silicon nitride layer 217 on each side of the field relief opening 219 cause each end portion of the LOCOS layer 214 to exhibit bird's beak profiles.

Next, as shown in FIG. 2D, following removal (etching) of the remaining silicon nitride layer 217, one or more implant steps (e.g., implants with mega-electron volt (MeV) implant energy) may be performed-e.g., in other areas of the substrate 202 to form various doped regions (e.g., n-type well, p-type well). In such examples, an annealing process 223 may be performed to remove or to repair crystalline defects that may have been formed as a result of the implant steps.

FIG. 2E then shows the result of forming an n-type drain drift region 220 and a p-type buried layer (PBL) 206, followed by etching of the pad oxide layer 210 (serving as a sacrificial oxide layer).

More particularly, as shown, the drain drift region 220 is formed in the semiconductor layer 208 below the LOCOS layer 214. In some examples, the drain drift region 220 can be formed by implanting phosphorus or other n-type dopants or impurities. In some examples, the implantation process can be followed by one or more thermal processes to extend or diffuse the implanted n-type dopants. The PBL 206 can be formed by implanting boron or other p-type dopants into the p-type semiconductor layer 208 over the NBL 204. In one example, the implantation process can be followed by one or more thermal processes to extend or diffuse the implanted p-type dopants below the drain drift region 220 and activate the implanted p-type dopants. In other examples, the formation of PBL 206 can be omitted.

After formation of the drain drift region 220 and the PBL 206, the pad oxide layer 210 is etched to remove the remaining portions thereof from the top surface of the semiconductor layer 208 on each side of the LOCOS layer 214.

Referring now to FIG. 2F, a result of a gate dielectric (e.g., gate oxide) formation stage is shown. In the FIG. 2F example, the DeNMOS transistor is formed with a gate oxide layer 219. In this example, the gate oxide layer 219 may be formed as a result of two thermal oxidation process steps—e.g., a combination of a first oxide layer 216 formed via a first thermal oxidation process at a first temperature and a second oxide layer 218 formed via a second thermal oxidation process at a second temperature which may be different than the first temperature. Thus, in some examples where the thermal oxidation process ranges from about 700 °C to about 1200 °C, the first temperature for the first thermal oxidation process can be set in an upper part of the range (e.g., about 1100 °C), while the second temperature for the second thermal oxidation process can be set in a lower part of the range (e.g., about 800 °C) or vice versa. Also, the terms first and second with regard to thermal oxidation processes or process steps are arbitrary and do not necessarily dictate a sequence of which process/step occurs before the other process/step.

Moreover, in some examples, the first oxide layer 216 can be considered a high voltage gate oxide (HVGOX) layer (e.g., used in other devices fabricated on the substrate 202 supporting a relatively high voltage, such as 5V to 8V) while the second gate oxide layer 218 can be considered a low voltage gate oxide (LVGOX) layer (e.g., used in yet other devices fabricated on the substrate 202 supporting a relatively low voltage, such as 1.8V) in view of different thicknesses (in the Z direction) of the first oxide layer 216 and the second oxide layer 218. In some examples, the first oxide layer 216 has a greater thickness as compared to the thickness of the second oxide layer 218. A thicker gate oxide layer between a gate electrode and an underlying channel enables higher gate operating voltages, as compared to a thinner gate oxide layer. An example thickness of the first oxide layer 216 can be about 10-15 nm and the second oxide layer 218 can be about 3-5 nm resulting in the thickness of the gate oxide layer 219 being about 13-20 nm. In other examples, the thicknesses of each of the first oxide layer 216, the second oxide layer 218, and the gate oxide layer 219 can be different than the examples above.

In addition to thermal oxidation, the formation of the gate oxide layer 219 can include, in some examples, other suitable processing such as a high temperature furnace operation or a rapid thermal process (RTP). In some examples, the gate oxide layer 219 can include silicon dioxide. Alternatively, a silicon oxynitride gate dielectric layer can be formed that is thicker but with a higher dielectric constant than that of silicon dioxide. In some other examples, the gate oxide layer 219 can be deposited using a chemical vapor deposition (CVD) process or an atomic layer deposition (ALD) process.

FIG. 2G-2I depict the formation of a second field relief layer 226. In some examples, the second field relief layer 226 includes nitride. Accordingly, as shown in FIG. 2G, a nitride layer 222 is deposited across the respective top surfaces of the LOCOS layer 214, the gate oxide layer 219, and the isolation regions 212. In some examples, the thickness (Z direction) of the nitride layer 222 is about 30-50 nm. A mask layer 224 is patterned, as shown in FIG. 2H, over the nitride layer 222. The nitride layer 222 is then etched and cleaned (e.g., wet or dry cleaning) to form the second field relief layer 226, as shown in FIG. 2I. In some examples, the width (X direction) of the second field relief layer 226 is about 400-600 nm and has the same or similar thickness (Z direction) as the nitride layer 222, e.g., about 30-50 nm.

As FIG. 2I further shows, the second field relief layer 226 is formed partially on the gate oxide layer 219 and partially on the LOCOS layer 214-more particularly, on a first end portion 213 (the bird's beak) of the LOCOS layer 214. The first end portion 213 of the LOCOS layer is on the opposing side of the LOCOS layer 214 relative to a second end portion 215 (the bird's beak) of the LOCOS layer 214. The second field relief layer 226 extends along the gate oxide layer 219 and slopes upward in the Z direction along the first end portion 213 of the LOCOS layer 214 before terminating at an edge along a top non-sloped surface of the LOCOS layer 214. Furthermore, in some examples, the second field relief layer 226 is formed over the drain drift region 220, e.g., disposed within the lateral dimensions or width (X direction) of the drain drift region 220.

As described above, the formation and positioning of the second field relief layer 226 (also referred to as a nitride layer 226 or a nitride field plate 226) reduces a vertical electric field strength under the area of the second field relief layer 226 thus mitigating the above-described adverse effects of TDDB, CHC degradation, GOI degradation, and/or other device performance, reliability and/or stability issues.

In a next intermediate stage, as shown in FIG. 2J, a gate stack for the DeNMOS transistor is formed. The gate stack includes the gate oxide (more generally, gate dielectric) layer 219, formed as described above in the context of FIG. 2F, and a gate electrode 228 formed at least partially on the gate oxide layer 219. In some examples, formation of the gate electrode 228 can include deposition of a polycrystalline silicon (e.g., polysilicon) layer using one or more silane-based precursors followed by a plasma etch process to define the shape of the gate electrode 228 and a wet or dry cleaning process to clean exposed surfaces. In other examples, a metal gate or CMOS-based replacement gate electrode process can also be used to form the gate electrode 228.

FIG. 2J also illustrates formation of sidewall spacer structures 230 along the lateral sides of the gate electrode 228. The sidewall spacer structures 230, in some examples, can include an oxide layer and a nitride layer. In one example, an oxide layer and a nitride layer are deposited over the entire wafer surface (not expressly shown), followed by a blanket anisotropic plasma etch process that removes portions of the oxide layer and portions of the nitride layer to form the sidewall spacer structures 230. In another example, nitride-only (or oxide-only) sidewall spacer structures can be implemented.

In addition, FIG. 2J shows formation of a source region 232 and a drain region 234 in the semiconductor layer 208 with an n-type dopant(s). More particularly, an implantation process is performed, in some examples, with a relatively shallow source/drain implant that does not penetrate the gate stacks and/or the field relief layers. Moreover, the drain region 234, in one example, contains an average dopant density at least 100 times that of the drain drift region 220 in which it is implanted. In some examples using an angled implant and/or using additional implants (e.g., lightly-doped drain (LDD) implants) prior to forming the sidewall spacer structures 230, or otherwise due to diffusion, the source region 232 can underlap the gate stack. Moreover, in some examples, the drain region 234 can underlap the LOCOS layer 214.

In some examples, semiconductor device 200 can include a body contact region (not expressly shown) in the semiconductor layer 208 with a p-type dopant(s). More particularly, a well implantation process can be performed to implant the body contact region between the source region 232 and the adjacent isolation region 212.

FIG. 2K illustrates formation of metal silicide layers 236 that respectively extend over the source region 232, the drain region 234, and the gate electrode 228. In some examples, a metal silicide process includes depositing a metal layer (e.g., Cobalt, not expressly shown), for example, using a blanket deposition process. In some examples, a silicide-blocking layer may be formed prior to depositing the metal layer to define areas exposed to the blanket deposition process. The semiconductor device 200 is then heated to form the metal silicide layers 236 (e.g., Cobalt silicide layer) over the intended areas and unreacted metal is subsequently removed in a wet stripping process.

FIG. 2K also shows formation of a pre-metal dielectric (PMD) layer 238, and conductive metal (e.g., tungsten) contacts 240 for the source region 232, the drain region 234, and the gate electrode 228.

Following the process flow of FIGS. 2A-2K, the finished wafer can then be separated (e.g., die singulation) to separate individual semiconductor dies from the starting wafer, and the dies can then be packaged to form integrated circuits or other packaged semiconductor devices.

Referring now to FIG. 3, a semiconductor device 300 is shown. The semiconductor device 300 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 300 is shown as including a DeMOS transistor, additional transistors (e.g., DeMOS and/or other transistor types) and/or other components that are not expressly shown may be integrated as part of semiconductor device 300 in various other examples. Also, while the DeMOS transistor in FIG. 3 is illustrated as a DeNMOS transistor, in one or more alternative examples, a DePMOS transistor can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 300 includes a semiconductor substrate 302, a first buried layer 304 disposed on the semiconductor substrate 302, a second buried layer 306 disposed on the first buried layer 304, and a semiconductor layer 308 disposed on the second buried layer 306. In some examples, the semiconductor layer 308 can be formed by an epitaxial process, and thus can be referred to as an epitaxial or “epi” layer 308. In the FIG. 3 example, the semiconductor substrate 302 is a p-type substrate, the second buried layer 306 is p-type buried layer (PBL 306), and the semiconductor layer 308 is a p-type semiconductor layer, while the first buried layer 304 is an n-type buried layer (NBL 304). In some examples, the PBL 306 has a dopant concentration greater than the semiconductor layer 308 and can be used to implement RESURF principles for SOA improvement for the semiconductor device 300. While two buried layers, e.g., the NBL 304 and the PBL 306, are shown in FIG. 3, other examples may include one or the other of the buried layers, or no buried layers.

Isolation regions 312 are disposed in the semiconductor layer 308. FIG. 3, being a cross-sectional view, illustrates the semiconductor device 300 (also referred to herein as the DeNMOS transistor 300) disposed between a pair of the isolation regions 312. The isolation regions 312 may laterally surround the DeNMOS transistor 300 in a top-down view (e.g., a layout view). In some examples, the isolation regions 312 are shallow trench isolation (STI) regions, while in other examples, the isolation regions 312 are deep trench (DT) regions, both STI and DT regions, or some combination thereof. Various other forms of component (e.g., transistor) isolation can be additionally or alternatively implemented in other examples.

As further shown, the DeNMOS transistor 300 includes a first field relief layer 314 disposed partially in the semiconductor layer 308 and partially above the semiconductor layer 308. The first field relief layer 314 is formed via a local oxidation of silicon (LOCOS) process, thus also being referred to herein as a LOCOS layer 314. The LOCOS layer 314, as will be further described below in the context of the FIGS. 4A-4L examples, is composed of a silicon oxide material and includes a first end portion 313 and a second end portion 315. First and second end portions 313 and 315 each have a bird's beak profile as is a common result of the LOCOS process.

The DeNMOS transistor 300 also includes a gate dielectric (e.g., gate oxide) layer 319 disposed on the semiconductor layer 308 adjacent the first end portion 313 of the LOCOS layer 314. The gate dielectric layer 319 is part of a gate stack as will be further described below. In the FIG. 3 example, the gate dielectric layer 319 has a first thickness T₁ below a second field relief layer 326 and a second thickness T₂ below a gate electrode 328. The first thickness T₁ is different than the second thickness T₂, e.g., as shown in FIG. 3, T₁ is less than T₂. An example of thickness T₁ can be about 10-15 nm and an example of thickness T₂ can be about 13-20 nm. In other examples, the thicknesses T₁ and T₂ of gate oxide layer 319 can be different than in the above examples.

As shown, the second field relief layer 326 is disposed partially on the gate dielectric layer 319 and partially on the LOCOS layer 314, more particularly, on the first end portion 313 (the bird's beak) of the LOCOS layer 314. The second field relief layer 326, as will be further described below in the context of the FIGS. 4A-4L examples, is composed of a nitride material. As shown, the second field relief layer 326 extends along the gate dielectric layer 319 and slopes upward in the Z direction along the first end portion 313 of the LOCOS layer 314 before terminating at an edge along a top non-sloped surface of the LOCOS layer 314. Advantageously, the second field relief layer 326 (also referred to as a nitride layer 326 or a nitride field plate 326) reduces a vertical electric field strength in the area under the second field relief layer 326 thus mitigating the above-described adverse effects of TDDB, CHC degradation, GOI degradation, and/or other device performance, reliability and/or stability issues.

The DeNMOS transistor 300 also includes an n-type drain drift region 320 disposed in the semiconductor layer 308, an n-type source region 332, and an n-type drain region 334 disposed in the drain drift region 320. The LOCOS 314 is disposed between the source region 332 and the drain region 334, partially above a surface of the semiconductor layer 308 and partially below the surface and in the drain drift region 320.

In some examples, DeNMOS transistor 300 can include a body contact region (not expressly shown) in the semiconductor layer 308 with a p-type dopant(s). More particularly, a well implantation process can be performed to implant the body contact region between the source region 332 and the adjacent isolation region 312.

The DeNMOS transistor 300 further includes a gate stack. The gate stack includes the gate dielectric layer 319 disposed on a portion of the surface of the semiconductor layer 308. The gate stack further includes the gate electrode 328 disposed over the gate dielectric layer 319 and at least a portion of the LOCOS layer 314. As shown in FIG. 3, the gate electrode 328 extends along the gate dielectric layer 319 and slopes upward in the Z direction along the first end portion 313 of the LOCOS layer 314 proximate to the source region 332 before terminating at an edge along a top non-sloped surface of the LOCOS layer 314 (e.g., prior to reaching the second end portion 115 of the LOCOS layer 314 proximate to the drain region 334). In some examples, the edge of the gate electrode 328 above the top non-sloped surface of the LOCOS layer 314 may terminate closer to the source region 332 or closer to the drain region 334 as compared to where it is shown terminating in FIG. 3.

Further as shown, the gate electrode 328 covers the second field relief layer 326 (e.g., forming a gate-covered field relief layer 326) such that the second field relief layer 326 is encapsulated between the gate dielectric layer 319, the LOCOS layer 314, and the gate electrode 328.

In some examples, the gate electrode 328 includes a polysilicon material. In other examples, the gate electrode 328 includes a metal or other suitable material. A channel region may be considered to extend across a portion of the semiconductor layer 308 under the gate electrode 328 between the source region 332 and the drain region 334.

As further shown in FIG. 3, the DeNMOS transistor 300 includes sidewall spacer structures 330 along the lateral sides of the gate electrode 328. The sidewall spacer structures 330 in one example include an oxide layer and a nitride layer (not expressly shown). In another example, a nitride-only (or oxide-only) sidewall spacer structure can be implemented.

The DeNMOS transistor 300 also includes metal silicide layers 336 that respectively extend over the source region 332, the drain region 334, and the gate electrode 328. The DeNMOS transistor 300 can include a single or multilevel metallization structure, with a pre-metal dielectric (PMD) layer 338 and conductive metal (e.g., tungsten) contacts 340, terminating on the respective metal silicide layers 336 for the source region 332, the drain region 334, and the gate electrode 328. In some examples, the metal silicide layers 336 can be formed from a Cobalt silicide (CoSiₓ) material.

Referring now to FIGS. 4A-4L, cross-sectional views are shown of a process flow for forming a semiconductor device 400, e.g., a DeNMOS transistor, in accordance with an example of the present disclosure. More particularly, the process flow of FIGS. 4A-4L for the semiconductor device 400 may represent an example of the formation of the semiconductor device 300 (DeNMOS transistor 300) of FIG. 3. Accordingly, unless otherwise specified, reference numerals in the 400s in FIGS. 4A-4L correspond to the same layers and structures with reference numerals in the 300s in FIG. 3 (e.g., a semiconductor substrate 402 in FIGS. 4A-4L corresponds to semiconductor substrate 302 in FIG. 3, NBL 404 corresponds to NBL 304, and so on).

FIG. 4A depicts an intermediate stage of formation of the semiconductor device 400. As shown, the semiconductor device 400 includes a p-type semiconductor substrate 402 which may be implemented as a silicon wafer, a silicon-on-sapphire wafer, a silicon carbide wafer, or the like. In some examples, a p-type semiconductor layer 408 is epitaxially grown on the semiconductor substrate 402. Then, n-type dopants or impurities (e.g., phosphorus, arsenic, antimony, etc.) are implanted in the semiconductor layer 408 to form an n-type buried layer (NBL) 404. In other examples, n-type dopants or impurities (e.g., phosphorus, etc.) are introduced to the p-type semiconductor substrate 402, and then a p-type semiconductor layer 408 is epitaxially grown on the semiconductor substrate 402. In other examples, the NBL 404 can be omitted.

FIG. 4A further depicts initial portions of a LOCOS process for forming a field relief layer. For example, as shown, a pad oxide layer 410 (e.g., silicon dioxide) is formed on the semiconductor layer 408, e.g., using a thermal oxidation process or a deposition process such as chemical vapor deposition (CVD). In some examples, the pad oxide layer 410 can be about 20 nm in thickness in the Z direction and be referred to as a thin oxide layer.

As further shown in the FIG. 4A example, a plurality of isolation regions 412 are also formed in the semiconductor layer 408 for electrical isolation between the DeNMOS transistor, to be formed as part of semiconductor device 400, and any adjacent devices and/or components (not expressly shown). Although FIG. 4A, being a cross-sectional view, illustrates multiple isolation regions 412, the isolation regions 412 may laterally surround the DeNMOS transistor in a top-down view (e.g., a layout view).

Next, FIG. 4B depicts a result of a next intermediate formation stage wherein a silicon nitride layer 417 (e.g., about 90 nm in thickness in the Z direction) is first deposited across the pad oxide layer 410, then etched (e.g., a dry etch) using a mask layer (not expressly shown) to form a field relief opening 419. A portion of the silicon nitride layer 417 resides on each side of the field relief opening 419 and extends over a top surface of an adjacent isolation region 412 and adjacent portions of the corresponding pad oxide layer 410. The pad oxide layer 410 in the field relief opening 419 may be removed during the nitride etch exposing a portion of the silicon of the semiconductor layer 408 below the pad oxide layer 410. In some examples, at least a portion of the pad oxide layer 410 may remain in the field relief opening 419 to protect the surface of the silicon during subsequent process steps. While dependent on the type of DeNMOS transistor being formed, in some examples, the field relief opening 419 can have a width in the X direction of about 100-300 nm (e.g., about 200 nm).

As further shown in FIG. 4B, a thermal oxidation process 421 (e.g., a LOCOS process) is applied. The thermal oxidation process is a relatively high-temperature (e.g., about 700 to about 1200 degrees Celsius (°C)) furnace oxidation that causes the silicon area of the semiconductor layer 408, uncovered by the silicon nitride layer 417 in the field relief opening 419, to oxidize and form a relatively thick layer of silicon dioxide in the field relief opening 419, e.g., a LOCOS layer 414, as shown in FIG. 4C.

The LOCOS layer 414 in FIG. 4C is formed partially above and partially below a top surface of the semiconductor layer 408. As an example, a LOCOS thickness (in the Z direction) can be about 100 nm, although the thickness can be dependent on the width of the field relief opening 419 and the operating parameters of the furnace oxidation. As is typical of a LOCOS process, the portions of the silicon nitride layer 417 on each side of the field relief opening 419 cause each end portion of the LOCOS layer 414 to exhibit bird's beak profiles.

Next, as shown in FIG. 4D, following removal (etching) of the remaining silicon nitride layer 417, one or more implant steps (e.g., implants with mega-electron volt (MeV) implant energy) may be performed-e.g., in other areas of the substrate 402 to form various doped regions (e.g., n-type well, p-type well). In such examples, an annealing process 423 may be performed to remove or to repair crystalline defects that may have been formed as a result of the implant steps.

FIG. 4E then shows the result of forming an n-type drain drift region 420 and a p-type buried layer (PBL) 406, followed by etching of the pad oxide layer 410 (serving as a sacrificial oxide layer).

More particularly, as shown, the drain drift region 420 is formed in the semiconductor layer 408 below the LOCOS layer 414. In some examples, the drain drift region 420 can be formed by implanting phosphorus or other n-type dopants or impurities. In some examples, the implantation process can be followed by one or more thermal processes to extend or diffuse the implanted n-type dopants. The PBL 406 can be formed by implanting boron or other p-type dopants into the p-type semiconductor layer 408 over the NBL 404. In one example, the implantation process can be followed by one or more thermal processes to extend or diffuse the implanted p-type dopants below the drain drift region 420 and activate the implanted p-type dopants. In other examples, the formation of PBL 406 can be omitted.

After formation of the drain drift region 420 and the PBL 406, the pad oxide layer 410 is etched to remove the remaining portions thereof from the top surface of the semiconductor layer 408 on each side of the LOCOS layer 414.

Referring now to FIG. 4F, a result of a first gate dielectric (e.g., gate oxide) formation stage is shown. More particularly, a first oxide layer 416 is formed via a first thermal oxidation process at a first temperature. In some examples, the first oxide layer 416 can be formed the same as or similar to the first oxide layer 216 (FIG. 2F) of the semiconductor device 200, e.g., a thermal oxidation process step set at about 1100 °C to form an HVGOX layer. Accordingly, an example thickness (Z direction) of the first oxide layer 416 can be about 10-15 nm.

In addition to thermal oxidation, the formation of the first oxide layer 416 can include, in some examples, other suitable processing such as a high temperature furnace operation or a rapid thermal process (RTP). In some examples, the first oxide layer 416 can include silicon dioxide. Alternatively, a silicon oxynitride gate dielectric layer can be formed that is thicker but with a higher dielectric constant than that of silicon dioxide. In some other examples, the first oxide layer 416 can be deposited using a chemical vapor deposition (CVD) process or an atomic layer deposition (ALD) process.

FIG. 4G-4I depict the formation of a second field relief layer 426. In some examples, the second field relief layer 426 includes nitride. Accordingly, starting in FIG. 4G, a nitride layer 422 is deposited across the respective top surfaces of the LOCOS layer 414, the first oxide layer 416, and the isolation regions 412. In some examples, the thickness (Z direction) of the nitride layer 422 is about 30-50 nm. A mask layer 424 is patterned, as shown in FIG. 4H, over the nitride layer 422. The nitride layer 422 is then etched and cleaned (e.g., wet or dry cleaning) to form the second field relief layer 426, as shown in FIG. 4I. In some examples, the width (X direction) of the second field relief layer 426 is about 400-600 nm and has the same or similar thickness (Z direction) as the nitride layer 422, e.g., about 30-50 nm.

As FIG. 4I further shows, the second field relief layer 426 is formed partially on the first oxide layer 416 and partially on the LOCOS layer 414-more particularly, on a first end portion 413 (the bird's beak) of the LOCOS layer 414. The first end portion 413 of the LOCOS 414 layer is on the opposing side of the LOCOS layer 414 relative to a second end portion 415 (the bird's beak) of the LOCOS layer 414. The second field relief layer 426 extends along the first oxide layer 416 and slopes upward in the Z direction along the first end portion 413 of the LOCOS layer 414 before terminating at an edge along a top non-sloped surface of the LOCOS layer 414. Furthermore, in some examples, the second field relief layer 426 is formed over the drain drift region 420, e.g., disposed within the lateral dimensions or width (X direction) of the drain drift region 420.

As described above, the formation and positioning of the second field relief layer 426 (also referred to as a nitride layer 426 or a nitride field plate 426) reduces a vertical electric field strength under the area of the second field relief layer 426 thus mitigating the above-described adverse effects of TDDB, CHC degradation, GOI degradation, and/or other device performance, reliability and/or stability issues. In some examples, an etch process (e.g., the nitride pullback process described with reference to FIG. 6K below) may be performed after forming the second field relief layer 426 prior to the second gate dielectric formation stage. In such examples, the gate oxide (e.g., the gate oxide 419 illustrated in FIG. 4K) may be less prone to issues stemming from plasma etch damage that may be present in the semiconductor layer 408 as a result of forming the second field relief layer 426 utilizing a plasma etch process.

Referring now to FIG. 4J, a result of a second gate dielectric (e.g., gate oxide) formation stage is shown. More particularly, a second oxide layer 418 is formed via a second thermal oxidation process at a second temperature. In some examples, the second oxide layer 418 can be formed the same as or similar to the second oxide layer 218 (FIG. 2F) of the semiconductor device 200, e.g., a thermal oxidation process step set at about 800 °C to form an LVGOX layer. In other examples, the second oxide layer 418 can be formed using alternative processes, as described above. Still further, in other examples, the temperatures of the first and second thermal oxidation process steps can be reversed. An example thickness (Z direction) of the second oxide layer 418 can be about 3-5 nm. In alternative examples, the first gate oxide layer 416 and the second gate oxide layer 418 can be formed in a different order.

As shown in FIG. 4K, a gate oxide layer 419 includes a combination of the first oxide layer 416 and the second oxide layer 418. In one example, a thickness T₁ of the gate oxide layer 419 below the second field relief layer 426 (first oxide layer 416) can be about 10-15 nm and a thickness T₂ of the gate oxide layer 419 between the second field relief layer 426 and the isolation region 412 (the combination of the first oxide layer 416 and the second oxide later 418) can be about 13-20 nm. In other examples, the thicknesses T₁ and T₂ can each be different than in the above examples.

Accordingly, while the second field relief layer 226 (FIG. 2I) in the semiconductor device 200 is formed after the forming of the first oxide layer 216 (e.g., HVGOX layer) and the forming of the second oxide later 218 (e.g., LVGOX layer), the second field relief layer 426 (FIG. 4I) in semiconductor device 400 is formed between the forming of the first oxide layer 416 (e.g., HVGOX layer) and the forming of the second oxide later 418 (e.g., LVGOX layer).

As further shown in FIG. 4K, a gate stack for the DeNMOS transistor is formed. The gate stack includes the gate oxide (more generally, gate dielectric) layer 419, formed as described above in the context of FIGS. 4I and 4J, and a gate electrode 428 formed at least partially on the gate oxide layer 419—e.g., on the portion of the gate oxide layer 419 having the T₂ thickness. In some examples, formation of the gate electrode 428 can include deposition of a polycrystalline silicon (e.g., polysilicon) layer using one or more silane-based precursors followed by a plasma etch process to define the shape of the gate electrode 428 and a wet or dry cleaning process to clean exposed surfaces. In other examples, a metal gate or CMOS-based replacement gate electrode process can also be used to form the gate electrode 428.

FIG. 4K also illustrates formation of sidewall spacer structures 430 along the lateral sides of the gate electrode 428. The sidewall spacer structures 430, in some examples, can include an oxide layer and a nitride layer. In one example, an oxide layer and a nitride layer are deposited over the entire wafer surface (not expressly shown), followed by a blanket anisotropic plasma etch process that removes portions of the oxide layer and portions of the nitride layer to form the sidewall spacer structures 430. In another example, nitride-only (or oxide-only) sidewall spacer structures can be implemented.

In addition, FIG. 4K shows formation of a source region 432 and a drain region 434 in the semiconductor layer 408 with an n-type dopant(s). More particularly, an implantation process is performed, in some examples, with a relatively shallow source/drain implant that does not penetrate the gate stacks and/or the field relief layers. Moreover, the drain region 434, in one example, contains an average dopant density at least 100 times that of the drain drift region 420 in which it is implanted. In some examples using an angled implant and/or using additional implants (e.g., lightly-doped drain (LDD) implants) prior to forming the sidewall spacer structures 430, or otherwise due to diffusion, the source region 432 can underlap the gate stack. Moreover, in some examples, the drain region 434 can underlap the LOCOS layer 414.

In some examples, semiconductor device 400 can include a body contact region (not expressly shown) in the semiconductor layer 408 with a p-type dopant(s). More particularly, a well implantation process can be performed to implant the body contact region between the source region 432 and the adjacent isolation region 412.

FIG. 4L illustrates formation of metal silicide layers 436 that respectively extend over the source region 432, the drain region 434, and the gate electrode 428. In some examples, a metal silicide process includes depositing a metal layer (e.g., Cobalt, not expressly shown), for example, using a blanket deposition process. In some examples, a silicide-blocking layer may be formed prior to depositing the metal layer to define areas exposed to the blanket deposition process. The semiconductor device 400 is then heated to form the metal silicide layers 436 (e.g., Cobalt silicide layer) over the intended areas and unreacted metal is subsequently removed in a wet stripping process.

FIG. 4L also shows formation of a pre-metal dielectric (PMD) layer 438, and conductive metal (e.g., tungsten) contacts 440 for the source region 432, the drain region 434, and the gate electrode 428.

Following the process flow of FIGS. 4A-4L, the finished wafer can then be separated (e.g., die singulation) to separate individual semiconductor dies from the starting wafer, and the dies can then be packaged to form integrated circuits or other packaged semiconductor devices.

Referring now to FIG. 5, a semiconductor device 500 is shown. The semiconductor device 500 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 500 is shown as including a DeMOS transistor, additional transistors (e.g., DeMOS and/or other transistor types) and/or other components that are not expressly shown may be integrated as part of semiconductor device 500 in various other examples. Also, while the DeMOS transistor in FIG. 5 is illustrated as a DeNMOS transistor, in one or more alternative examples, a DePMOS transistor can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 500 includes a semiconductor substrate 502, a first buried layer 504 disposed on the semiconductor substrate 502, a second buried layer 506 disposed on the first buried layer 504, and a semiconductor layer 508 disposed on the second buried layer 506. In some examples, the semiconductor layer 508 can be formed by an epitaxial process, and thus can be referred to as an epitaxial or “epi” layer 508. In the FIG. 5 example, the semiconductor substrate 502 is a p-type substrate, the second buried layer 506 is p-type buried layer (PBL 506), and the semiconductor layer 508 is a p-type semiconductor layer, while the first buried layer 504 is an n-type buried layer (NBL 504). In some examples, the PBL 506 has a dopant concentration greater than the semiconductor layer 508 and can be used to implement RESURF principles for SOA improvement for the semiconductor device 500. While two buried layers, e.g., the NBL 504 and the PBL 506, are shown in FIG. 5, other examples may include one or the other of the buried layers, or no buried layers.

Isolation regions 512 are disposed in the semiconductor layer 508. FIG. 5, being a cross-sectional view, illustrates the semiconductor device 500 (also referred to herein as the DeNMOS transistor 500) disposed between a pair of the isolation regions 512. The isolation regions 512 may laterally surround the DeNMOS transistor 500 in a top-down view (e.g., a layout view). In some examples, the isolation regions 512 are shallow trench isolation (STI) regions, while in other examples, the isolation regions 512 are deep trench (DT) regions, both STI and DT regions, or some combination thereof. Various other forms of component (e.g., transistor) isolation can be additionally or alternatively implemented in other examples.

As further shown, the DeNMOS transistor 500 includes a first field relief layer 514 disposed partially in the semiconductor layer 508 and partially above the semiconductor layer 508. The first field relief layer 514 is formed via a local oxidation of silicon (LOCOS) process, thus also being referred to herein as a LOCOS layer 514. The LOCOS layer 514, as will be further described below in the context of the FIGS. 6A-6N examples, is composed of a silicon oxide material and includes a first end portion 511 and a second end portion 513. First and second end portions 511 and 513 each have a bird's beak profile as is a common result of the LOCOS process.

The DeNMOS transistor 500 also includes a gate dielectric (e.g., gate oxide) layer 519 disposed on the semiconductor layer 508 adjacent the first end portion 511 of the LOCOS layer 514. The gate dielectric layer 519 is part of a gate stack as will be further described below. In the FIG. 5 example, the gate dielectric layer 519 has a first thickness T₁ below a second field relief layer 526 and a second thickness T₂ below a gate electrode 528. The first thickness T₁ is different than the second thickness T₂, as shown in FIG. 5, T₁ is less than T₂. An example of thickness T₁ can be about 10-15 nm and an example of thickness T₂ can be about 13-20 nm. In other examples, the thicknesses T₁ and T₂ can each be different than in the above examples.

As shown, the second field relief layer 526 is disposed partially on the gate dielectric layer 519 and partially on the LOCOS layer 514, more particularly, on the first end portion 511 (the bird's beak) of the LOCOS layer 514. The second field relief layer 526, as will be further described below in the context of the FIGS. 6A-6N examples, is composed of a nitride material. As shown, the second field relief layer 526 extends along the gate dielectric layer 519 and slopes upward in the Z direction along the first end portion 511 of the LOCOS layer 514 before terminating at an edge along a top non-sloped surface of the LOCOS layer 514. Advantageously, the second field relief layer 526 (also referred to as a nitride layer 526 or a nitride field plate 526) reduces a vertical electric field strength under the area of the second field relief layer 526 thus mitigating the above-described adverse effects of TDDB, CHC degradation, GOI degradation, and/or other device performance, reliability and/or stability issues.

The DeNMOS transistor 500 also includes an n-type drain drift region 520 disposed in the semiconductor layer 508, an n-type source region 532, and an n-type drain region 534 disposed in the drain drift region 520. The LOCOS 514 is disposed between the source region 532 and the drain region 534, partially above a surface of the semiconductor layer 508 and partially below the surface and in the drain drift region 520.

In some examples, DeNMOS transistor 500 can include a body contact region (not expressly shown) in the semiconductor layer 508 with a p-type dopant(s). More particularly, a well implantation process can be performed to implant the body contact region between the source region 532 and the adjacent isolation region 512.

The DeNMOS transistor 500 further includes a gate stack. The gate stack includes the gate dielectric layer 519 disposed on a portion of the surface of the semiconductor layer 508. The gate stack further includes the gate electrode 528 disposed over the gate dielectric layer 519 and at least a portion of the LOCOS layer 514. As shown in FIG. 5, the gate electrode 528 extends along the gate dielectric layer 519 and slopes upward in the Z direction along the first end portion 511 of the LOCOS layer 514 proximate to the source region 532 before terminating at an edge along a top non-sloped surface of the LOCOS layer 514 (e.g., prior to reaching the second end portion 115 of the LOCOS layer 514 proximate to the drain region 534). In some examples, the edge of the gate electrode 528 above the top non-sloped surface of the LOCOS layer 514 may terminate closer to the source region 532 or closer to the drain region 534 as compared to where it is shown terminating in FIG. 5.

Further as shown, the gate electrode 528 covers the second field relief layer 526 (e.g., forming a gate-covered field relief layer 526) such that the second field relief layer 526 is encapsulated between the gate dielectric layer 519, the LOCOS layer 514, and the gate electrode 528.

In some examples, the gate electrode 528 includes a polysilicon material. In other examples, the gate electrode 528 includes a metal or other suitable material. A channel region may be considered to extend across a portion of the semiconductor layer 508 under the gate electrode 528 between the source region 532 and the drain region 534.

As further shown in FIG. 5, the DeNMOS transistor 500 includes sidewall spacer structures 530 along the lateral sides of the gate electrode 528. The sidewall spacer structures 530 in one example include an oxide layer and a nitride layer (not expressly shown). In another example, a nitride-only (or oxide-only) sidewall spacer structure can be implemented.

The DeNMOS transistor 500 also includes metal silicide layers 536 that respectively extend over the source region 532, the drain region 534, and the gate electrode 528. The DeNMOS transistor 500 can include a single or multilevel metallization structure, with a pre-metal dielectric (PMD) layer 538 and conductive metal (e.g., tungsten) contacts 540, terminating on the respective metal silicide layers 536 for the source region 532, the drain region 534, and the gate electrode 528. In some examples, the metal silicide layers 536 can be formed from a Cobalt silicide (CoSiₓ) material.

Referring now to FIGS. 6A-6N, cross-sectional views are shown of a process flow for forming a semiconductor device 600, e.g., a DeNMOS transistor, in accordance with an example of the present disclosure. More particularly, the process flow of FIGS. 6A-6N for the semiconductor device 600 may represent an example of the formation of the semiconductor device 500 (DeNMOS transistor 500) of FIG. 5. Accordingly, unless otherwise specified, reference numerals in the 600s in FIGS. 6A-6N correspond to the same layers and structures with reference numerals in the 500s in FIG. 5 (e.g., a semiconductor substrate 602 in FIGS. 6A-6N corresponds to semiconductor substrate 502 in FIG. 5, NBL 604 corresponds to NBL 504, and so on).

FIG. 6A depicts an intermediate stage of formation of the semiconductor device 600. As shown, the semiconductor device 600 includes a p-type semiconductor substrate 602 which may be implemented as a silicon wafer, a silicon-on-sapphire wafer, a silicon carbide wafer, or the like. In some examples, a p-type semiconductor layer 608 is epitaxially grown on the semiconductor substrate 602. Then, n-type dopants or impurities (e.g., phosphorus, etc.) are implanted in the semiconductor layer 608 to form an n-type buried layer (NBL) 604. In other examples, n-type dopants or impurities (e.g., phosphorus, arsenic, antimony, etc.) are introduced to the p-type semiconductor substrate 602, and then a p-type semiconductor layer 608 is epitaxially grown on the semiconductor substrate 602. In other examples, the NBL 604 can be omitted.

FIG. 6A further depicts initial portions of a LOCOS process for forming a field relief layer. For example, as shown, a pad oxide layer 610 (e.g., silicon dioxide) is formed on the semiconductor layer 608, e.g., using a thermal oxidation process or a deposition process such as chemical vapor deposition (CVD). In some examples, the pad oxide layer 610 can be about 20 nm in thickness in the Z direction and be referred to as a thin oxide layer.

As further shown in the FIG. 6A example, a plurality of isolation regions 612 are also formed in the semiconductor layer 608 for electrical isolation between the DeNMOS transistor, to be formed as part of semiconductor device 600, and any adjacent devices and/or components (not expressly shown). Although FIG. 6A, being a cross-sectional view, illustrates multiple isolation regions 612, the isolation regions 612 may laterally surround the DeNMOS transistor in a top-down view (e.g., a layout view).

Next, FIG. 6B depicts a result of a next intermediate formation stage wherein a silicon nitride layer 617 (e.g., about 90 nm in thickness in the Z direction) is first deposited across the pad oxide layer 610, then etched (e.g., a dry etch) using a mask layer (not expressly shown) to form a field relief opening 619. A portion of the silicon nitride layer 617 resides on each side of the field relief opening 619 and extends over a top surface of an adjacent isolation region 612 and adjacent portions of the corresponding pad oxide layer 610. The pad oxide layer 610 in the field relief opening 619 may be removed during the nitride etch exposing a portion of the silicon of the semiconductor layer 608 below the pad oxide layer 610. In some examples, at least a portion of the pad oxide layer 610 may remain in the field relief opening 619 to protect the surface of the silicon during subsequent process steps. While dependent on the type of DeNMOS transistor being formed, in some examples, the field relief opening 619 can have a width in the X direction of about 100-300 nm (e.g., about 200 nm).

As further shown in FIG. 6B, a thermal oxidation process 621 (e.g., a LOCOS process) is applied. The thermal oxidation process is a relatively high-temperature (e.g., about 700 to about 1200 degrees Celsius (°C)) furnace oxidation that causes the silicon area of the semiconductor layer 608, uncovered by the silicon nitride layer 617 in the field relief opening 619, to oxidize and form a relatively thick layer of silicon dioxide in the field relief opening 619, e.g., a LOCOS layer 614, as shown in FIG. 6C.

The LOCOS layer 614 in FIG. 6C is formed partially above and partially below a top surface of the semiconductor layer 608. As an example, a LOCOS thickness (in the Z direction) can be about 100 nm, although the thickness can be dependent on the width of the field relief opening 619 and the operating parameters of the furnace oxidation. As is typical of a LOCOS process, the portions of the silicon nitride layer 617 on each side of the field relief opening 619 cause each end portion of the LOCOS layer 614 to exhibit bird's beak profiles.

Next, as shown in FIG. 6D, following removal (etching) of the remaining silicon nitride layer 617, one or more implant steps (e.g., implants with mega-electron volt (MeV) implant energy) may be performed—e.g., in other areas of the substrate 602 to form various doped regions (e.g., n-type well, p-type well). In such examples, an annealing process 623 may be performed to remove or to repair crystalline defects that may have been formed as a result of the implant steps.

FIG. 6E then shows the result of etching the pad oxide layer 610 (serving as a sacrificial oxide layer) to remove the remaining portions thereof from the top surface of the semiconductor layer 608 on each side of the LOCOS layer 614.

Next, FIG. 6F shows the formation of an oxide layer 615 on the surface of the semiconductor layer 608 exposed following the removal of the pad oxide layer 610 in FIG. 6E. In some examples, the oxide layer 615 can be formed in the same or similar manner as the pad oxide layer 610 or as one or more of the above-described gate oxide layers. The oxide layer 615 can be about 10-15 nm in thickness, in some examples. In other examples, the thickness of the oxide layer 615 can be less than 10 nm (e.g., 8 nm, 6 nm, 4 nm, or even less) or greater than 15 nm (e.g., 18 nm, 21 nm, 25 nm, or even greater).

In a next intermediate stage, as shown in FIG. 6G, an n-type drain drift region 620 is formed in the semiconductor layer 608 below the LOCOS layer 614. In some examples, the drain drift region 620 can be formed by implanting phosphorus or other n-type dopants or impurities. In some examples, the implantation process can be followed by one or more thermal processes to extend or diffuse the implanted n-type dopants. FIG. 6G also illustrates formation of a p-type buried layer (PBL) 606. For example, the PBL 606 can be formed by implanting boron or other p-type dopants into the p-type semiconductor layer 608 over the NBL 604. In one example, the implantation process can be followed by one or more thermal processes to extend or diffuse the implanted p-type dopants below the drain drift region 620 and activate the implanted p-type dopants. In other examples, the formation of PBL 606 can be omitted.

FIG. 6H-6J depict the formation of a second field relief layer 626. In some examples, the second field relief layer 626 includes nitride. Accordingly, starting in FIG. 6H, a nitride layer 622 is deposited across the respective top surfaces of the LOCOS layer 614, the oxide layer 615, and the isolation regions 612. In some examples, the thickness (Z direction) of the nitride layer 622 is about 30-50 nm. A mask layer 624 is patterned, as shown in FIG. 6I, over the nitride layer 622. The nitride layer 622 is then etched and cleaned (e.g., wet or dry cleaning) to form the second field relief layer 626, as shown in FIG. 6J. In some examples, the width (X direction) of the second field relief layer 626 is about 400-600 nm and has the same or similar thickness (Z direction) as the nitride layer 622, e.g., about 30-50 nm.

As FIG. 6J further shows, the second field relief layer 626 is formed partially on the oxide layer 615 and partially on the LOCOS layer 614—more particularly, on a first end portion 611 (the bird's beak) of the LOCOS layer 614. The first end portion 611 of the LOCOS 614 layer is on the opposing side of the LOCOS layer 614 relative to a second end portion 613 (the bird's beak) of the LOCOS layer 614. The second field relief layer 626 extends along the oxide layer 615 and slopes upward in the Z direction along the first end portion 611 of the LOCOS layer 614 before terminating at an edge along a top non-sloped surface of the LOCOS layer 614. Furthermore, in some examples, the second field relief layer 626 is formed over the drain drift region 620, e.g., disposed within the lateral dimensions or width (X direction) of the drain drift region 620.

As described above, the formation and positioning of the second field relief layer 626 (also referred to as a nitride layer 626 or a nitride field plate 626) reduces a vertical electric field strength under the area of the second field relief layer 626 thus mitigating the above-described adverse effects of TDDB, CHC degradation, GOI degradation, and/or other device performance, reliability and/or stability issues.

Still further, FIG. 6J depicts the second field relief layer 626 having an initial nitride width W_{N0} (X direction) and an initial nitride thickness T_{N0} (Z direction). An etch process (e.g., wet etch process, nitride pullback process) is then performed on the second field relief layer 626, as shown in FIG. 6K, such that the initial nitride width W_{N0} and/or the initial nitride thickness T_{N0} is/are reduced resulting in a reduced nitride width W_{N1} and/or a reduced nitride thickness T_{N1}. Additionally, as shown in FIG. 6K, the exposed portions of the oxide layer 615 are removed during the etch process-with the exception of the portion of the oxide layer 615 below the second field relief layer 626. In other examples, at least a portion of the exposed portions of the oxide layer 615 remains outside the second field relief layer 626.

In some examples, one advantage of the etch process (e.g., the nitride pullback process) is to remove an edge portion of the second field relief layer 626 such that robust gate oxide can be formed for the DeNMOS transistor. Removing the edge portion of the second field relief layer 626 may facilitate subsequent oxidation process steps to anneal damage in the semiconductor layer 608 (e.g., plasma etch damage incurred to the semiconductor layer 608 while the second field relief layer 626 is patterned) or to consume the damaged portion of the semiconductor layer 608. In this manner, the gate oxide (e.g., gate oxide 619 illustrated in FIG. 6M below) is expected to be more robust-e.g., being less prone to issues stemming from the plasma etch damage. In some examples, such a nitride pullback process may be performed for the DeNMOS transistor-e.g., after forming the second field relief layer 426 as shown in FIG. 4J. In other words, the nitride pullback process may be inserted prior to forming the second oxide layer 418 such that potential damage to the semiconductor layer 408 (e.g., plasma etch damage incurred to the semiconductor layer 408 while the second field relief layer 426 is patterned) may be annealed or removed while the second oxide layer 418 is formed.

Referring now to FIG. 6L, a result of a gate dielectric (e.g., gate oxide) formation stage is shown. In this example, the gate oxide layer 619 may be formed as a result of two thermal oxidation process steps-e.g., a combination of a first oxide layer 616 formed via a first thermal oxidation process at a first temperature and a second oxide layer 618 formed via a second thermal oxidation process at a second temperature which may be different than the first temperature. More particularly, in some examples, the first oxide layer 616 can be formed the same as or similar to the first oxide layer 216 (HVGOX layer) of FIG. 2F, while the second oxide layer 618 can be formed the same as or similar to the second oxide layer 218 (LVGOX layer) of FIG. 2F. The thicknesses (Z direction) of the first oxide layer 616 and the second oxide layer 618 can be the same as or similar to the HVGOX and LVGOX layers described above- or can be different in other examples.

As shown in FIG. 6M, the gate oxide layer 619 can be considered to include a combination of the first oxide layer 616 and the second oxide layer 618, as well as the remaining portion of the oxide layer 615 below the second field relief layer 626. In one example, a thickness T₁ of the gate oxide layer 619 below the second field relief layer 626 (the remaining portion of the oxide layer 615) can be about 10-15 nm and a thickness T₂ of the gate oxide layer 619 between the second field relief layer 626 and the isolation region 612 (the combination of the first oxide layer 616 and the second oxide later 618) can be about 13-20 nm. The respective thicknesses of T₁ and T₂ can be different in other examples.

Accordingly, while the second field relief layer 226 (FIG. 2I) in the semiconductor device 200 is formed after the forming of the first oxide layer 216 (e.g., HVGOX layer) and the forming of the second oxide later 218 (e.g., LVGOX layer), the second field relief layer 626 (FIG. 6M) in semiconductor device 600 is formed before the forming of the first oxide layer 616 (e.g., HVGOX layer) and the forming of the second oxide later 618 (e.g., LVGOX layer).

As further shown in FIG. 6M, a gate stack for the DeNMOS transistor is formed. The gate stack includes the gate oxide (more generally, gate dielectric) layer 619, formed as described above in the context of FIG. 6L, and a gate electrode 628 formed at least partially on the gate oxide layer 619—e.g., on the portion of the gate oxide layer 619 having the T₂ thickness. In some examples, formation of the gate electrode 628 can include deposition of a polycrystalline silicon (e.g., polysilicon) layer using one or more silane-based precursors followed by a plasma etch process to define the shape of the gate electrode 628 and a wet or dry cleaning process to clean exposed surfaces. In other examples, a metal gate or CMOS-based replacement gate electrode process can also be used to form the gate electrode 628.

FIG. 6M also illustrates formation of sidewall spacer structures 630 along the lateral sides of the gate electrode 628. The sidewall spacer structures 630, in some examples, can include an oxide layer and a nitride layer. In one example, an oxide layer and a nitride layer are deposited over the entire wafer surface (not expressly shown), followed by a blanket anisotropic plasma etch process that removes portions of the oxide layer and portions of the nitride layer to form the sidewall spacer structures 630. In another example, nitride-only (or oxide-only) sidewall spacer structures can be implemented.

In addition, FIG. 6M shows formation of a source region 632 and a drain region 634 in the semiconductor layer 608 with an n-type dopant(s). More particularly, an implantation process is performed, in some examples, with a relatively shallow source/drain implant that does not penetrate the gate stacks and/or the field relief layers. Moreover, the drain region 634, in one example, contains an average dopant density at least 100 times that of the drain drift region 620 in which it is implanted. In some examples using an angled implant and/or using additional implants (e.g., lightly-doped drain (LDD) implants) prior to forming the sidewall spacer structures 630, or otherwise due to diffusion, the source region 632 can underlap the gate stack. Moreover, in some examples, the drain region 634 can underlap the LOCOS layer 614.

In some examples, semiconductor device 600 can include a body contact region (not expressly shown) in the semiconductor layer 608 with a p-type dopant(s). More particularly, a well implantation process can be performed to implant the body contact region between the source region 632 and the adjacent isolation region 612.

FIG. 6N illustrates formation of metal silicide layers 636 that respectively extend over the source region 632, the drain region 634, and the gate electrode 628. In some examples, a metal silicide process includes depositing a metal layer (e.g., Cobalt, not expressly shown), for example, using a blanket deposition process. In some examples, a silicide-blocking layer may be formed prior to depositing the metal layer to define areas exposed to the blanket deposition process. The semiconductor device 600 is then heated to form the metal silicide layers 636 (e.g., Cobalt silicide layer) over the intended areas and unreacted metal is subsequently removed in a wet stripping process.

FIG. 6N also shows formation of a pre-metal dielectric (PMD) layer 638, and conductive metal (e.g., tungsten) contacts 640 for the source region 632, the drain region 634, and the gate electrode 628.

Following the process flow of FIGS. 6A-6N, the finished wafer can then be separated (e.g., die singulation) to separate individual semiconductor dies from the starting wafer, and the dies can then be packaged to form integrated circuits or other packaged semiconductor devices.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a drain region disposed in the semiconductor layer;
a source region disposed in the semiconductor layer;
a first field relief layer disposed partially in the semiconductor layer between the drain region and the source region;
a gate electrode disposed between the drain region and the source region, the gate electrode disposed partially on the first field relief layer; and
a second field relief layer disposed at least partially on the first field relief layer and covered by the gate electrode.

2. The semiconductor device of claim 1, wherein the second field relief layer includes nitride.

3. The semiconductor device of claim 1, wherein the second field relief layer is disposed on a first end portion of the first field relief layer, the first end portion being proximate the source region.

4. The semiconductor device of claim 3, wherein the first end portion includes a bird's beak profile.

5. The semiconductor device of claim 1, wherein the second field relief layer is disposed above a drift region in the semiconductor layer, the drift region extending from the drain region towards the source region.

6. The semiconductor device of claim 1, further comprising:
a gate dielectric layer disposed on the semiconductor layer, wherein the gate electrode is partially disposed on the gate dielectric layer.

7. The semiconductor device of claim 6, wherein the second field relief layer is partially disposed on the gate dielectric layer.

8. The semiconductor device of claim 7, wherein the gate dielectric layer has a first thickness below the second field relief layer and a second thickness below the gate electrode, the first thickness being different than the second thickness.

9. A semiconductor device, comprising:
a semiconductor layer;
a drain region disposed in the semiconductor layer;
a source region disposed in the semiconductor layer;
a silicon oxide layer disposed partially in the semiconductor layer between the drain region and the source region;
a gate stack disposed between the drain region and the source region, the gate stack including a gate electrode and a gate oxide layer, the gate electrode disposed partially on the silicon oxide layer and partially on the gate oxide layer; and
a nitride layer disposed partially on the silicon oxide layer, partially on the gate oxide layer, and covered by the gate electrode.

10. The semiconductor device of claim 9, wherein the nitride layer is disposed on a portion of the silicon oxide layer proximate the source region, the portion of the silicon oxide layer including a bird's beak profile.

11. The semiconductor device of claim 9, wherein the nitride layer is disposed above a drift region in the semiconductor layer, the drain region extending from the drain region towards the source region.

12. The semiconductor device of claim 9, wherein the gate oxide layer has a first thickness below the nitride layer and a second thickness below the gate electrode, the first thickness being less than the second thickness.

13. A method of fabricating a semiconductor device, comprising:
forming a first field relief layer partially in a semiconductor layer, the first field relief layer being formed via a local oxidation of silicon (LOCOS) process;
forming a second field relief layer at least partially on the first field relief layer, the second field relief layer including nitride;
forming a gate electrode, the gate electrode disposed partially on the first field relief layer and covering the second field relief layer; and
forming a drain region and a source region, the drain region being proximate to a first end of the first field relief layer and the source region being proximate to a second end of the first field relief layer.

14. The method of claim 13, further comprising:
forming a gate dielectric layer on the semiconductor layer, the gate dielectric layer being partially below the gate electrode and partially below the second field relief layer.

15. The method of claim 14, wherein the gate dielectric layer includes a first layer formed via a first process using a first temperature and a second layer formed on the first layer via a second process using a second temperature, the first temperature being greater than the second temperature.

16. The method of claim 15, wherein the second field relief layer is formed after the forming of the first layer and the forming of the second layer of the gate dielectric layer.

17. The method of claim 15, wherein the second field relief layer is formed between the forming of the first layer and the forming of the second layer of the gate dielectric layer.

18. The method of claim 15, wherein the second field relief layer is formed before the forming of the first layer and the forming of the second layer of the gate dielectric layer.

19. The method of claim 18, further comprising:
removing a first portion of the second field relief layer before the forming of the first layer and the forming of the second layer of the gate dielectric layer, wherein a second portion of the second field relief layer, remaining after the removing of the first portion, is proximate the source region.

20. The method of claim 14, wherein the gate dielectric layer has a first thickness below the second field relief layer and a second thickness below the gate electrode, the first thickness being different than the second thickness.

21. The method of claim 13, further comprising:
reducing a lateral dimension of the second field relief layer before forming the gate electrode.
